(19) United States
(12) Patent Application Publication
(10) Pub. No.: US 2026/0311647 A1
(43) Pub. Date: Oct. 8, 2026

(54) DISPLAY DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Yosuke TSUKAMOTO, Atsugi, Kanagawa (JP); Kensuke YOSHIZUMI, Atsugi, Kanagawa (JP); Susumu KAWASHIMA, Atsugi, Kanagawa (JP)

(21) Appl. No.: 19/482,826

(22) PCT Filed: May 13, 2024
(86) PCT No.: PCT/IB2024/054607

§ 371 Date: Nov. 10, 2025

(30) Foreign Application Priority Data
May 19, 2023 (JP) 2023-082714

(51) Int. Cl. G09G 3/3266; G09G 3/3275

(52) U.S. Cl. CPC G09G 3/3266; G09G 3/3275; G09G 2310/0286; G09G 2320/0214; G09G 2320/0242; G09G 2330/021

(57) ABSTRACT

To provide a display device in which the degree of freedom in the external shape can be increased. A display portion includes a first region, a second region, and a third region, the first to third regions each include a pixel circuit, the second region includes a component of a gate driver circuit, and the third region includes a component of a source driver circuit. A vertical transistor can be used as transistors that are components of the driver circuits. The vertical transistor has an advantage in that it can easily have a short channel length and a large channel width and thus can easily increase the on-state current. In addition, the vertical transistor can have a small occupation area, and components are easily distributed in a plurality of pixels.

### TECHNICAL FIELD

One embodiment of the present invention relates to a display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an imaging device, an electronic device, a lighting device, an input device, an input/output device, a driving method thereof, and a manufacturing method thereof. A semiconductor device generally means a device that can function by utilizing semiconductor characteristics.

### BACKGROUND ART

For the purpose of downsizing or improving the degree of freedom of an electronic device designing, making a display device having a narrow bezel has been required. In order to make a display device having a narrow bezel, it is effective to provide a pixel portion and a driver circuit portion monolithically over the same substrate.

In addition, an attempt has been made to manufacture a display device having a narrow bezel and an increased degree of freedom in the external shape by employing a structure in which gate driver circuits are distributed in a pixel region (see Patent Document 1 and Non-Patent Document 1).

### REFERENCE

### Patent Document

[Patent Document 1] PCT International Publication No. 2014-069529

### Non-Patent Document

[Non-Patent Document 1] H. Yoshida et. al.: “Flexible Flat-Panel Display Designs with Gate Driver Circuits Integrated within the Pixel Area”, SID 2015 Digest, pp. 879-882 (2015)

### SUMMARY OF THE INVENTION

### Problems to be Solved by the Invention

In a display device, pixels are arranged near intersection points of gate lines and source lines, transistors in the pixels are turned on by signals output from a gate driver circuit to the gate lines, and data output from a source driver circuit to the source lines are written to the pixels.

IC chips are used in the source driver circuit because the source driver circuit needs to operate at higher speed than the gate driver circuit. The IC chips can be mounted in a bezel region. As the resolution of the display device increases, a larger number of IC chips are mounted, which is an impediment to narrowing a bezel and lowering cost. Therefore, the source driver circuit is also desired to be monolithically formed.

Furthermore, in Patent Document 1 and Non-Patent Document 1, the degree of freedom in the external shape of the display device is increased by providing a monolithic gate driver circuit in a pixel region, whereas the source driver circuit is provided in a bezel region. Therefore, arrangement of a source driver circuit needs to be devised in order to further increase the degree of freedom in its external shape.

In view of the above, an object of one embodiment of the present invention is to provide a display device having a high degree of freedom in the external shape. Another object is to provide a display device having a narrow bezel. Another object is to provide a display device in which a driver circuit is monolithically formed. Another object is to provide a novel semiconductor device, a novel display device, or the like.

Note that the description of these objects does not preclude the presence of other objects. Note that one embodiment of the present invention does not necessarily achieve all these objects. Note that objects other than these can be derived from the description of the specification, the drawings, the claims, and the like.

### Means for Solving the Problems

One embodiment of the present invention relates to a display device having an increased degree of freedom in the external shape.

One embodiment of the present invention is a display device including a display portion including a first region, a second region, and a third region. The first region includes a first pixel, the second region includes a second pixel, the third region includes a third pixel, and the first to third pixels each include a component of a pixel circuit. The second pixel includes a component of a first circuit, and the third pixel includes a component of a second circuit.

The first region is a region except the second region and the third region in the display portion, and the second and third regions can each have a belt-like shape and can be arranged to be orthogonal to each other.

The first circuit can have a function of a gate driver circuit, and the second circuit can have a function of a source driver circuit.

The first circuit can include a first shift register circuit, and the second circuit can include a second shift register circuit, a first latch circuit, a second latch circuit, and a source follower circuit.

Another embodiment of the present invention is a display device including a first region, a second region, and a third region in a display portion, the first region includes a first pixel, the second region includes a second pixel, the third region includes a third pixel, the first to third pixels each include a component of a pixel circuit, the second pixel includes a component of a gate driver circuit, and the third pixel includes a component of a source driver circuit. The first region is a region except the second region and the third region in the display portion, and the second and third regions each have a belt-like shape and are arranged to be orthogonal to each other.

The gate driver circuit can include a first shift register circuit, and the source driver circuit can include a second shift register circuit, a first latch circuit, a second latch circuit, and a source follower circuit.

Each of the first to third pixels preferably includes a light-emitting device.

Each of the first to third pixels preferably includes a transistor including a metal oxide in a semiconductor layer. A channel formation region of the transistor may be provided along a side surface of an insulating layer.

The display device can include a region where pixels are provided along a curved line in a periphery of the display portion. In addition, the display device can include a curved surface in the display portion. Furthermore, an opening portion can be provided in the first region.

Another embodiment of the present invention is an electronic device including the display device described above, a camera, and a region where the opening portion and a lens of the camera overlap with each other.

### Effect of the Invention

According to one embodiment of the present invention, a display device having a high degree of freedom in the external shape can be provided. Alternatively, a display device with a narrow bezel can be provided. Alternatively, a display device in which a driver circuit is monolithically formed can be provided. Alternatively, a novel semiconductor device, a novel display device, or the like can be provided.

Note that the description of these effects does not preclude the presence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1A is a diagram illustrating a display device. FIG. 1B is an enlarged view illustrating a display device.

FIG. 2A is a diagram simply illustrating a gate driver circuit. FIG. 2B is a diagram simply illustrating a source driver circuit.

FIG. 3A is a block diagram of a shift register circuit. FIG. 3B is a block diagram of a gate driver circuit. FIG. 3C is a block diagram of a source driver circuit.

FIG. 4A is a block diagram of a source driver circuit. FIG. 4B is a block diagram illustrating a latch circuit L1, a latch circuit L2, and a source follower circuit.

FIG. 5A is a circuit diagram illustrating a shift register circuit. FIG. 5B and FIG. 5C are timing charts illustrating operations of a gate driver circuit.

FIG. 6A is a block diagram illustrating a shift register circuit. FIG. 6B is a circuit diagram illustrating a shift register. FIG. 6C and FIG. 6D are timing charts illustrating operations of a gate driver circuit.

FIG. 7 is a circuit diagram illustrating a latch circuit L1, a latch circuit L2, and a source follower circuit.

FIG. 8 is a diagram illustrating components of a gate driver circuit distributed in a pixel.

FIG. 9 is a diagram illustrating components of a source driver circuit distributed in a pixel.

FIG. 10 is a diagram illustrating components of a source driver circuit distributed in a pixel.

FIG. 11 is a diagram illustrating components of a source driver circuit distributed in a pixel.

FIG. 12 is a diagram illustrating components of a source driver circuit distributed in a pixel.

FIG. 13A is a diagram simply illustrating arrangement of pixels PIX. FIG. 13B is a diagram illustrating a structure of a pixel PIX. FIG. 13C and FIG. 13D are diagrams each illustrating a pixel circuit.

FIG. 14A to FIG. 14D are diagrams illustrating arrangement of a gate driver circuit and a source driver circuit.

FIG. 15A is a diagram illustrating an example in which an end portion of a display portion has curvature. FIG. 15B is a diagram illustrating an example in which an opening portion is provided in the display portion.

FIG. 16A and FIG. 16B are diagrams illustrating an example of a display portion having a curved surface.

FIG. 17A to FIG. 17K are diagrams each illustrating an external shape of a display device.

FIG. 18A to FIG. 18C are diagrams illustrating a structure example of a display panel.

FIG. 19A and FIG. 19B are diagrams each illustrating a structure example of a display panel.

FIG. 20A to FIG. 20F are diagrams each illustrating a structure example of pixels.

FIG. 21A and FIG. 21B are diagrams illustrating a vertical transistor.

FIG. 22A is a cross-sectional view illustrating an example of a display device. FIG. 22B and FIG. 22C are cross-sectional views each illustrating an example of a transistor.

FIG. 23 is a cross-sectional view illustrating an example of a display device.

FIG. 24A and FIG. 24B are diagrams each illustrating an example of an electronic device. FIG. 24C is a diagram illustrating a camera module.

FIG. 25A and FIG. 25B are cross-sectional views each illustrating an example of an electronic device.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component in drawings is sometimes omitted or changed as appropriate between drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are separately arranged in a plurality of positions.

In addition, one conductor has a plurality of functions such as a wiring, an electrode, and a terminal in some cases. In this specification, a plurality of names are used for the same component in some cases. Furthermore, even in the case where components are illustrated in a circuit diagram as if they were directly connected to each other, the components may actually be connected to each other through one conductor or a plurality of conductors. In this specification, even such a structure is included in the category of direct connection.

### Embodiment 1

In this embodiment, a display device according to one embodiment of the present invention will be described with reference to drawings.

One embodiment of the present invention is a display device having a narrow bezel and high degree of freedom in the external shape. In the display device, a gate driver circuit and a source driver circuit are provided inside a display portion.

The display portion includes a first region, a second region, and a third region; the first region includes a first pixel; the second region includes a second pixel; and the third region includes a third pixel. Each of the first to third pixels includes a component of a pixel circuit; the second pixel includes a component of the gate driver circuit; and the third pixel includes a component of the source driver circuit.

Vertical transistors can be used as transistors that are components of the gate driver circuit and the source driver circuit. The vertical transistor includes a channel formation region along a side surface of an opening portion provided in an insulator, and has a structure in which the channel length is easily shortened and the channel width is easily increased, so that the on-state current can be easily increased. In particular, the vertical transistor is suitable for the source driver circuit that operates at high speed. In addition, the vertical transistor has advantages in that its occupied area can be reduced and components can be easily distributed in a plurality of pixels.

When the gate driver circuit and the source driver circuit are provided inside the display portion in this manner, a region where the driver circuit is to be provided can be unnecessary in a bezel region. Accordingly, the display device can have a narrower bezel. Furthermore, a selection signal and a data signal are supplied from a driver circuit inside the display portion to an end of the display portion, whereby the degree of freedom in the peripheral shape of the display portion can be increased.

Note that in this embodiment, when both the gate driver circuit and the source driver circuit are mentioned and are not distinguished from each other, they are simply referred to as a driver circuit in some cases.

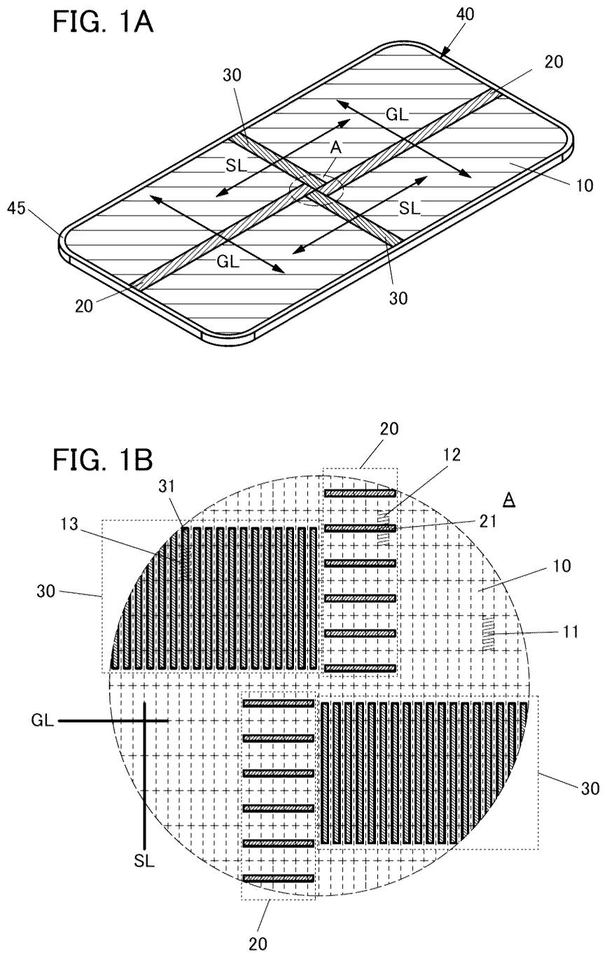

FIG. 1A is a perspective view illustrating a display device of one embodiment of the present invention. FIG. 1B is an enlarged plan view of a region A illustrated in FIG. 1A.

The display device includes a display portion 40 provided over a substrate 45. The display portion 40 includes a region 10, a region 20, and a region 30. The region 20 and the region 30 are band-shaped and can be provided to be orthogonal to each other. The region 10 is a region except the region 20 and the region 30 in the display portion 40 and can be provided in contact with the region 20 and the region 30.

Pixels for performing display are provided to be arrayed in the display portion 40. Here, a pixel included in the region 10 is referred to as a pixel 11, a pixel included in the region 20 is referred to as a pixel 12, and a pixel included in the region 30 is referred to as a pixel 13. Note that the pixels 11, 12, and 13 can function as subpixels when the display device performs color display.

Pixel circuits for driving the display elements are arranged in the pixels 11, 12, and 13. Across a plurality of pixels 12, components 21 included in the gate driver circuit are distributed in the pixels. In addition, across a plurality of pixels 13, components 21 included in the source driver circuit are distributed in the pixels. Here, the components included in the driver circuit refer to, for example, a transistor, a capacitor, a wiring, or a circuit including them.

The region 20 can be provided at such a position that the display portion 40 is roughly divided into two in the first direction, as illustrated in FIG. 1A, for example. The region 30 can be provided at such a position that the display portion 40 is roughly divided into two in the second direction. The second direction is orthogonal to the first direction.

Note that since the pixel area is limited, it is preferable that one pixel not include both a component of the gate driver circuit and a component of the source driver circuit. Thus, as illustrated in FIG. 1B, a plurality of regions 20 and a plurality of regions 30 are provided such that the region 20 and the region 30 do not overlap with each other.

When the driver circuits are provided inside the display portion in this manner, the bezel can be narrowed and the degree of freedom in the external shape of the display device can be increased.

Note that even when the plurality of regions 20 are provided, components in the plurality of regions 20 are electrically connected to each other through a wiring or the like, whereby one gate driver circuit can be formed. In addition, even when the plurality of regions 30 are provided, components in the plurality of regions 30 are electrically connected to each other through a wiring or the like, whereby one source driver circuit can be formed.

Alternatively, an independent gate driver circuit may be formed in each of the plurality of regions 20. In addition, an independent source driver circuit may be formed in each of the plurality of regions 30. Providing a plurality of driver circuits enables parallel operations, which enables the display device to operate at high speed.

As illustrated in FIG. 1A, a gate line GL electrically connected to the gate driver circuit can be placed to be orthogonal to the region 20 and to extend to the region 10 placed on both sides of the region 20. A source line SL electrically connected to the source driver circuit can be placed to be orthogonal to the region 30 and to extend to the region 10 placed on both sides of the region 30.

When the driver circuits are provided in such positions, the distance between an output portion of the driver circuit and an end portion of a wiring can be shortened. Accordingly, wiring capacitance and wiring resistance can be reduced, distortion of signal waveforms can be inhibited, and high-speed operation can be promoted.

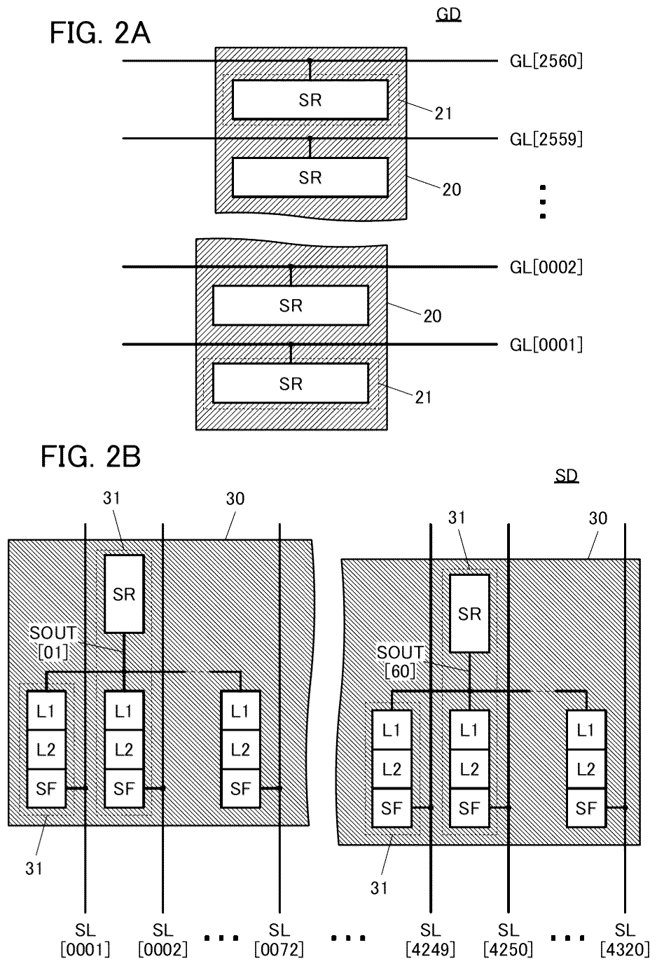

FIG. 2A is a diagram simply illustrating a gate driver circuit GD provided in the region 20. The gate driver circuit GD includes a plurality of components 21. As the component 21, a shift register circuit SR can be used. An output portion of the shift register circuit SR can be electrically connected to the gate line GL.

For example, when the display portion 40 has a resolution of 4320 (1440×RGB)×2560, the 2560-stage shift register circuits SR are cascade-connected. With the operation of the cascade-connected shift register circuits SR, selection signals can be sequentially output to gate lines GL[0001] to [2560].

FIG. 2B is a diagram simply illustrating the source driver circuit provided in the region 30. A source driver circuit SD includes a plurality of components 31. The component 31 can have a structure in which the shift register circuit SR, the latch circuit L1, the latch circuit L2, and a source follower circuit SF are connected in series. Alternatively, a structure in which the shift register circuit SR is removed from the above structure can be employed. An output portion of the source follower circuit SF can be electrically connected to the source line SL.

In order to process an enormous amount of data at high speed, the source driver circuit SD performs an operation of writing data signals to a plurality of latch circuits L1 with signals output from one shift register circuit SR. Data signals are input to the plurality of latch circuits L1 from a signal output portion SOUT of the shift register circuit SR, and the latch circuits L1 output the data signals to the source lines SL through the latch circuits L2 and the source follower circuit SF connected in series.

For example, when the display portion 40 has a resolution of 4320 (1440×RGB)×2560, 72 latch circuits L1 are electrically connected to the signal output portion SOUT of one shift register circuit SR.

With such a structure, data signals output to the source lines SL[0001] to [0072] can be stored in the latch circuits L1 in response to a signal output from a signal output portion SOUT[01] of the shift register circuit in the first stage. Similarly, data signals output to source lines SL[4249] to [4320] can be stored in the latch circuits L1 in response to a signal output from a signal output portion SOUT[60] of the shift register circuit SR in the last stage.

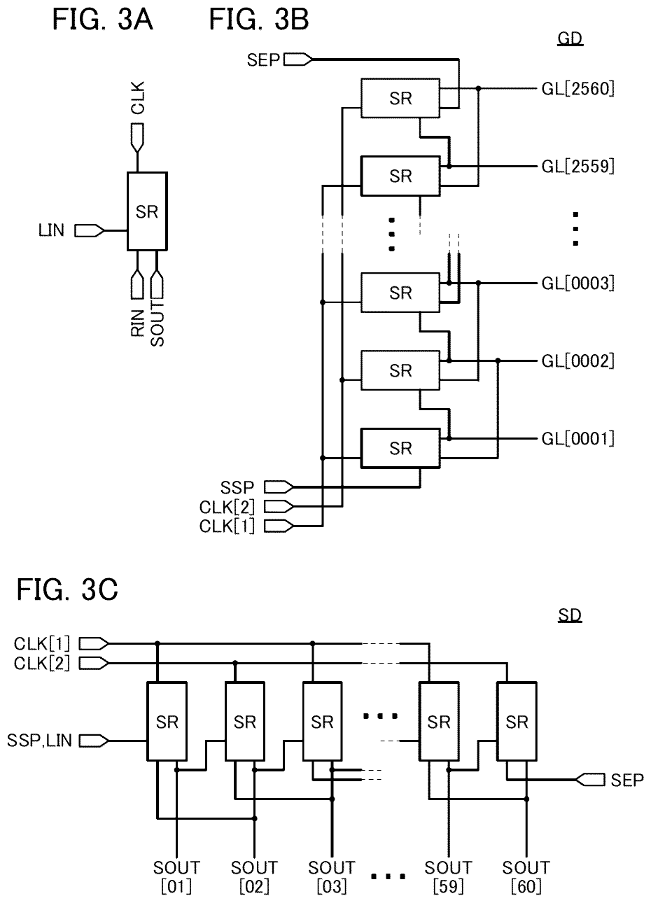

FIG. 3A is a block diagram illustrating an example of the shift register circuit SR illustrated in FIG. 2A and FIG. 2B. The shift register circuit SR includes a clock signal input portion CLK, a signal input portion LIN, a signal input portion RIN, and the signal output portion SOUT. An output signal of the shift register circuit SR in the previous stage is input to the signal input portion LIN, and an output signal of the shift register circuit SR in the subsequent stage is input to the signal input portion RIN.

FIG. 3B is a block diagram illustrating the gate driver circuit GD provided in the region 20. The shift register circuits SR corresponding to the number of gate lines GL are cascade-connected, a clock signal CLK[1] is input to a shift register circuit SR in an odd-numbered stage, and a clock signal CLK[2] is input to a shift register circuit in an even-numbered stage. The clock signal CLK[2] is an inverted signal of the clock signal CLK[1]. A start pulse (SSP) is input to the signal input portion LIN of the shift register circuit SR in the first stage, and an end pulse (SEP) is input to the signal input portion RIN of the shift register circuit SR in the last stage. In addition, a shift register circuit SR in a dummy stage may be provided to generate SEP.

By forming the gate driver circuit GD having such a structure, selection signals can be sequentially output to the gate lines GL[0001] to [2560] when the display portion 40 has the above-described resolution.

FIG. 3C is a block diagram illustrating a sequential circuit portion of the source driver circuit SD provided in the region 30. The basic structure can be similar to that of the gate driver circuit GD. Note that in the source driver circuit SD, a plurality of source lines SL correspond to one-stage shift register circuit; thus, it is preferable that the number of stages of the cascade-connected shift register circuits SR be reduced and high-speed operation be facilitated.

When the display portion 40 has the above-described resolution, signals can be sequentially output to the signal output portions SOUT[01] to [60].

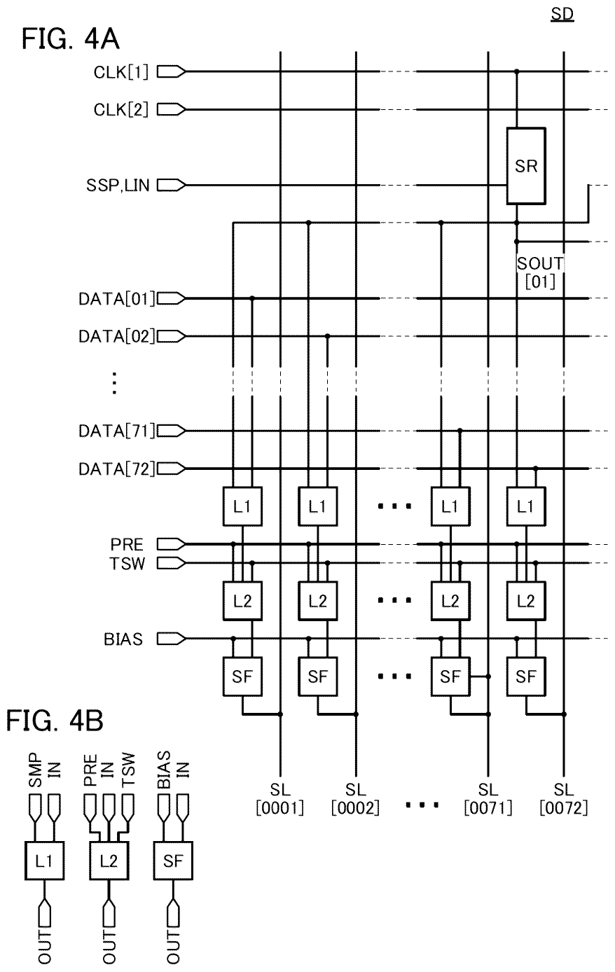

FIG. 4A is a block diagram illustrating the latch circuit L1, the latch circuit L2, and the source follower circuit SF that are electrically connected to the signal output portion SOUT[01] of the shift register circuit SR. FIG. 4B is a block diagram illustrating the latch circuit L1, the latch circuit L2, and the source follower circuit SF.

The latch circuit L1 includes a sampling signal input portion SMP, a data input portion IN, and a signal output portion OUT. An output signal from the shift register circuit SR is input to the sampling signal input portion SMP. A data signal DATA is input to the data input portion IN.

The latch circuit L2 includes a precharge signal input portion PRE, a transfer signal input portion TSW, a data input portion IN, and a signal output portion OUT. An output signal of the latch circuit L1 is input to the data input portion IN.

The source follower circuit SF includes a bias signal input portion BIAS, a data input portion IN, and a signal output portion OUT. An output signal of the latch circuit L2 is input to the data input portion IN. The source line SL is electrically connected to the signal output portion OUT.

By forming the source driver circuit SD having such a structure, data signals can be sequentially output to the source lines SL[0001] to [4320] when the display portion 40 has the above-described resolution.

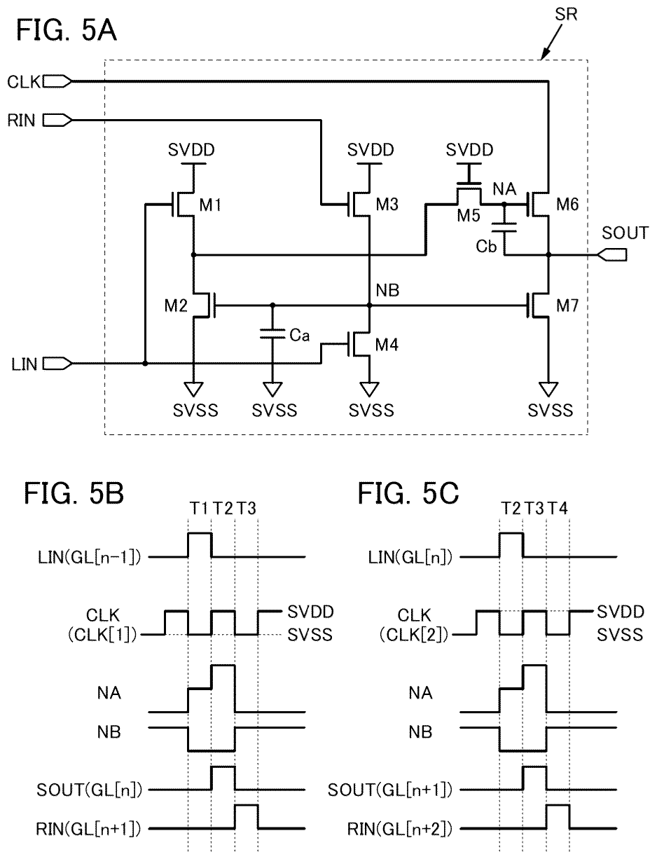

FIG. 5A illustrates an example of a specific circuit diagram of the shift register circuit SR. The shift register circuit SR can be formed of seven transistors (transistors M1 to M7) and two capacitors (capacitor Ca and Cb).

One of a source and a drain of the transistor MI is electrically connected to one of a source and a drain of the transistor M2 and one of a source and a drain of the transistor M5. A gate of the transistor M2 is electrically connected to one electrode of the capacitor Ca, one of a source and a drain of the transistor M3, one of a source and a drain of the transistor M4, and a gate of the transistor M7. The other of the source and the drain of the transistor M5 is electrically connected to a gate of the transistor M6 and one electrode of the capacitor Cb. One of a source and a drain of the transistor M6 is electrically connected to the other electrode of the capacitor Cb and one of a source and a drain of the transistor M7.

A high potential power supply line (SVDD) is electrically connected to the other of the source and the drain of the transistor M1, the other of the source and the drain of the transistor M3, and a gate of the transistor M5. A low potential power supply line (SVSS) is electrically connected to the other of the source and the drain of the transistor M2, the other of the source and the drain of the transistor M4, the other of the source and the drain of the transistor M7, and the other electrode of the capacitor Ca.

The gates of the transistor MI and the transistor M4 function as the signal input portion LIN. A gate of the transistor M3 functions as the signal input portion RIN. The other of the source and the drain of the transistor M6 functions as the clock signal input portion CLK. The one of the source and the drain of the transistor M6, the other electrode of the capacitor Cb, and the one of the source and the drain of the transistor M7 function as the signal output portion SOUT.

Here, a point (a wiring, an electrode, or the like) that is electrically connected to the other of the source and the drain of the transistor M5, the gate of the transistor M6, and the one electrode of the capacitor Cb is referred to as a node NA. In addition, a point (a wiring, an electrode, or the like) that is electrically connected to the gate of the transistor M2, the one electrode of the capacitor Ca, the one of the source and the drain of the transistor M3, the one of the source and the drain of the transistor M4, and the gate of the transistor M7 is referred to as a node NB.

Next, operation in the case where the shift register circuit SR illustrated in FIG. 5A is used in the structure of the gate driver circuit GD in FIG. 3B is described. FIG. 5B is a timing chart illustrating the operation of the shift register circuit SR electrically connected to the gate line GL in the n-th row (n is an odd number). FIG. 5C is a timing chart illustrating the operation of the shift register circuit SR electrically connected to the gate line GL in the n+1-th row.

As illustrated in FIG. 3B and FIG. 3C, the clock signal input in an odd-numbered stage is different from the clock signal input in an even-numbered stage; however, basic operation is substantially the same. Here, the operation of the shift register circuit SR electrically connected to the gate line GL in the n-th row is mainly described with reference to FIG. 5B.

Here, a signal input to the signal input portion LIN is referred to as a LIN signal, a signal input to the clock signal input portion CLK is referred to as a CLK signal, a signal input to the signal input portion RIN is referred to as a RIN signal, and a signal output from the signal output portion SOUT is referred to as a SOUT signal.

In Period T1, a high-level potential LIN signal is input to the gate of the transistor M1 from the gate line GL in the (n−1)-th row, so that the transistor M1 is turned on to precharge the node NA. Furthermore, the high-level potential LIN signal is also input to the gate of the transistor M4 from the gate line GL in the (n−1)-th row, so that the transistor M4 is turned on to discharge the node NB to a low-level potential.

At this time, the transistor M6 is in an on state, the transistor M7 is in an off state, and the CLK signal is at a low-level potential (SVSS) and thus the SOUT signal is at a low-level potential. A potential difference of SVDD-SVSS is stored in the capacitor Cb.

In a period T2, when the CLK signal is switched to be at a high-level potential (SVDD), the transistor M6 is turned on, the transistor M7 is turned off, and thus the SOUT signal is a high-level potential.

In addition, as the gate line GL in the n-th row is charged, the potential of the node NA increases owing to capacitive coupling of the capacitor Cb and the gate voltage of the transistor M6 increases, which compensate for the charge operation of the gate line GL in the n-th row. At this time, the potential difference of SVDD-SVSS is stored in the capacitor Cb and thus the potential of the node NA increases to 2×SVDD-SVSS.

Here, the source potential of the transistor M5 is higher than the gate potential of the transistor M5, so that the transistor M5 is turned off. Therefore, the source-drain voltage (V_{ds}) of the transistor M2 does not increase unnecessarily and the stress to the transistor M2 can be inhibited.

At this time, the SOUT signal at a high-level potential is input to the shift register circuit SR in the next stage as the LIN signal, and precharge of the node NA and discharge of the node NB are performed in the shift register circuit SR in the next stage.

In a period T3, the CLK signal is changed to a low-level potential. Furthermore, the SOUT signal at a high-level potential in the shift register circuit SR in the next stage is input to the gate of the transistor M3 as the RIN signal, so that the transistor M3 is turned on, and the node NB is charged to a high-level potential.

At this time, the transistor M2 is turned on, so that the transistor M5 is turned on, the node NA is discharged to a low-level potential, and the transistor M6 is turned off. The transistor M7 is turned on, and the SOUT signal is at a low-level potential. A potential difference of SVDD-SVSS is stored in the capacitor Ca.

Through the above operations, the operation of the shift register circuit SR electrically connected to the gate line GL in the n-th row is completed. From this point until the restart of operation in the next frame, the on state of the transistor M7 is kept and the SOUT signal is kept at a low-level potential by the potential difference retained in the capacitor Ca.

Also in the case where the shift register circuit SR illustrated in FIG. 5A is used in the structure of the source driver circuit SD illustrated in FIG. 3C and FIG. 4, operation can be performed in a manner similar to that of the gate driver circuit GD.

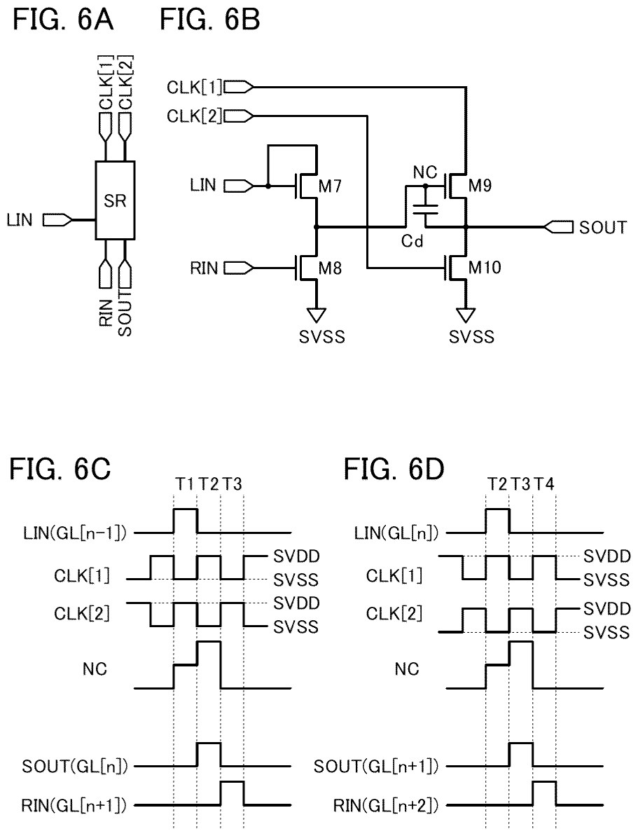

As the shift register circuit SR, a circuit having a structure simpler than that in FIG. 5A can also be used. For example, FIG. 6A is a block diagram of the shift register circuit SR with a simple structure, and FIG. 6B is a diagram illustrating an example of a specific circuit thereof.

The shift register circuit SR illustrated in FIG. 6A includes a clock signal input portion CLK[1], a clock signal input portion CLK[2], the signal input portion LIN, the signal input portion RIN, and the signal output portion SOUT. An output signal of the shift register circuit SR in the previous stage is input to the signal input portion LIN, and an output signal of the shift register circuit SR in the subsequent stage is input to the signal input portion RIN.

The shift register circuit SR can be formed of four transistors (transistors M7 to M10) and one capacitor (capacitor Cd). One of the source and the drain of the transistor M7 is electrically connected to one of a source and a drain of the transistor M8, a gate of the transistor M9, and one electrode of the capacitor Cd. One of a source and a drain of the transistor M9 is electrically connected to one of a source and a drain of the transistor M10, a gate, and the other electrode of the capacitor Cd.

The other of the source and the drain of the transistor M8 and the other of the source and the drain of the transistor M10 are each electrically connected to the low potential power supply line (SVSS).

The gate and the other of the source and the drain of the transistor M7 function as the signal input portion LIN. A gate of the transistor M8 functions as the signal input portion RIN. The other of the source and the drain of the transistor M9 functions as the clock signal input portion CLK1. The other of the source and the drain of the transistor M10 functions as the clock signal input portion CLK2. The one of the source and the drain of the transistor M9, the other electrode of the capacitor Cd, and the one of the source and the drain of the transistor M10 function as the signal output portion SOUT.

Here, a point (a wiring or the like) that is electrically connected to the one of the source and the drain of the transistor M7, the one of the source and the drain of the transistor M8, the gate of the transistor M9, and the one electrode of the capacitor Cd is referred to as a node NC.

FIG. 6C and FIG. 6D are timing charts illustrating operations in the case where the shift register circuit SR illustrated in FIG. 6B is used in the structure of the gate driver circuit GD in FIG. 3B. FIG. 6C corresponds to the shift register circuit SR electrically connected to the gate line GL in the n-th row (n is an odd number greater than or equal to 1), and FIG. 6D corresponds to the shift register circuit SR electrically connected to the gate line GL in the n+1-th row. In addition, a CLK[2] signal is an inverted signal of a CLK[1] signal.

In Period T1, when the high-level potential LIN signal is input from the gate line GL in the n−1-th row to the gate and the other of the source and the drain of the transistor M7, the transistors M7 and M9 are turned on and the node NC is precharged.

At this time, since the CLK[1] signal is at a low-level potential (SVSS) and the CLK[2] signal is at a high-level potential (SVDD), the transistor M10 is in an on state and the SOUT signal is at a low-level potential. A potential difference of SVDD-SVSS is stored in the capacitor Cd.

In Period T2, when the CLK[1] signal is changed to a high-level potential and the CLK[2] signal is changed to a low-level potential, the transistor M9 is turned on, the transistor M10 is turned off, and thus the SOUT signal is at a high-level potential.

In addition, as the gate line GL in the n-th row is charged, the potential of the node NC increases owing to capacitive coupling of the capacitor Cd and the gate voltage of the transistor M9 increases, which compensate for the charge operation of the gate line GL in the n-th row. At this time, the potential difference of SVDD-SVSS is stored in the capacitor Cd, and thus the node NA increases to 2×SVDD-SVSS.

At this time, the SOUT signal at a high-level potential is input to the shift register circuit SR in the next stage as the LIN signal, and precharge of the node NC is performed in the shift register circuit SR in the next stage.

In Period T3, the CLK[1] signal is changed to a low-level potential and the CLK[2] signal is changed to a high-level potential. Furthermore, the SOUT signal having a high-level potential in the shift register circuit SR in the next stage is input to the gate of the transistor M8 as the RIN signal, so that the transistor M8 is turned on and the node NC is discharged to a low-level potential.

At this time, the transistor M9 is turned off, the transistor M10 is turned on, and thus the SOUT signal is at a low-level potential.

Through the above operations, the operation of the shift register circuit SR electrically connected to the gate line GL in the n-th row is completed.

Also in the case where the shift register circuit SR illustrated in FIG. 6B is used in the structure of the source driver circuit SD illustrated in FIG. 3C and FIG. 4, operation can be performed in a manner similar to that of the gate driver circuit GD.

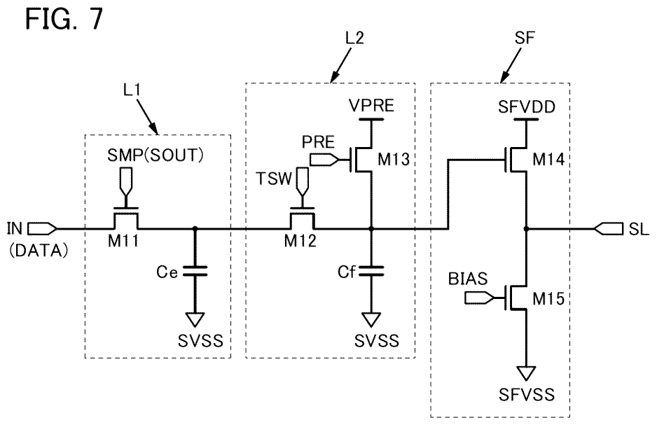

FIG. 7 is an example of a circuit diagram of the latch circuit L1, the latch circuit L2, and the source follower circuit SF included in the source driver circuit SD.

The latch circuit L1 can be formed of one transistor (transistor M11) and one capacitor (capacitor Ce). The latch circuit L2 can be formed of two transistors (transistor M12 and transistor M13) and one capacitor (capacitor Cf). The source follower circuit SF can be formed of two transistors (transistor M14 and transistor M15).

One of a source and a drain of the transistor M11 is electrically connected to one electrode of the capacitor Ce and one of a source and a drain of the transistor M12. The other of the source and the drain of the transistor M12 is electrically connected to one of a source and a drain of the transistor M13, one electrode of the capacitor Cf, and a gate of the transistor M14. One of a source and a drain of the transistor M14 is electrically connected to one of a source and a drain of the transistor M15.

A wiring VPRE for supplying a precharge potential is electrically connected to the other of the source and the drain of the transistor M13. The other of the source and the drain of the transistor M14 is electrically connected to a high-potential power supply line (SFSVDD). A first low-potential power supply line (SVSS) is electrically connected to the other electrode of the capacitor Ce and the other electrode of the capacitor Cf. The other of the source and the drain of the transistor M15 is electrically connected to a second low-potential power supply line (SFVSS). Note that the first low potential power supply line and the second low potential power supply line may be electrically connected to each other.

The other of the source and the drain of the transistor M11 functions as the data input portion IN. A gate of the transistor M11 functions as the sampling signal input portion SMP. The sampling signal input portion SMP is electrically connected to the signal output portion SOUT of the shift register circuit SR.

A gate of the transistor M12 functions as the transfer signal input portion TSW. A gate of the transistor M13 functions as the precharge signal input portion PRE. A gate of the transistor M15 functions as the bias signal input portion BIAS. The transistor M15 functions as a current source when an appropriate potential (bias signal) is input to the gate of the transistor M15.

When a high-level potential output signal is input from the shift register circuit SR to the sampling signal input portion SMP of the latch circuit L1, the transistor M11 is turned on, and data in the n-th frame (n is an integer greater than or equal to 2) is written to the capacitor Ce. At this time, the transistor M12 in the latch circuit L2 is in an off state, data of the n−1-th frame is written to the capacitor Cf, and data is output to the source line SL through the source follower circuit SF.

Data of the n-th frame can be output to the source line SL as follows. First, a high-level potential signal is input to the precharge signal input portion PRE to turn on the transistor M13, so that a precharge potential is supplied and data of the n−1-th frame written to the capacitor Cf is reset. Then, a high-level potential signal is input to the transfer signal input portion TSW to turn on the transistor M12, so that data written to the capacitor Ce is transferred to the capacitor Cf. With this operation, data of the n-th frame can be output from the source follower circuit SF to the source line SL.

Note that data output to the source line by the above operation is read in the pixels in the same row with parallel operation. That is, the circuit illustrated in FIG. 7 can perform line sequential driving.

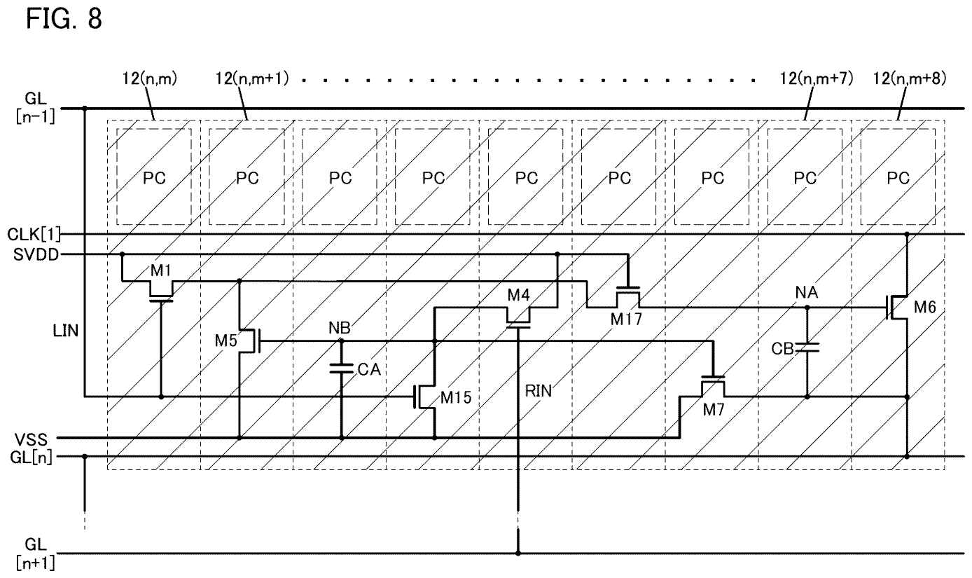

FIG. 8 is a diagram illustrating an example in which components of the shift register circuit SR illustrated in FIG. 5A included in the gate driver circuit GD are distributed in the plurality of pixels 12 in the display portion 40.

FIG. 8 illustrates the pixels 12(n,m) to 12(n,m+8) in the n-th row as an example of the pixels 12 arranged in the region 20 illustrated in FIG. 1A and FIG. 1B. Note that n and m are each an integer. The pixels 12(n,m) to 12(n,m+8) each include a pixel circuit PC. The pixel circuit PC is a circuit for driving a display element for performing display.

Furthermore, the pixels 12(n,m) to 12(n,m+8) can each include one or more components (transistors or capacitors) of the shift register circuit SR. For example, although FIG. 8 illustrates an example in which one component is provided in one pixel 12, two or more components may be provided. To avoid interfering with the arrangement of the pixel circuit PC, the number of components of the shift register circuit SR provided in one pixel 12 is preferably one or two.

In addition, any of the pixels 12(n,m) to 12(n,m+8) may be a pixel in which no component of the shift register circuit SR is placed. Although FIG. 8 illustrates an example in which components of one shift register circuit SR are distributed in nine pixels 12, one embodiment of the present invention is not limited thereto, and the components may be distributed in eight or fewer pixels 12 or ten or more pixels 12.

Furthermore, the positional relation between the components of the pixel circuit PC and the components of the shift register circuit SR may be any positional relation, and the components can be placed in a way that facilitates easy layout. The pixel circuit PC and the shift register circuit SR may be electrically connected to a common power supply line or the like.

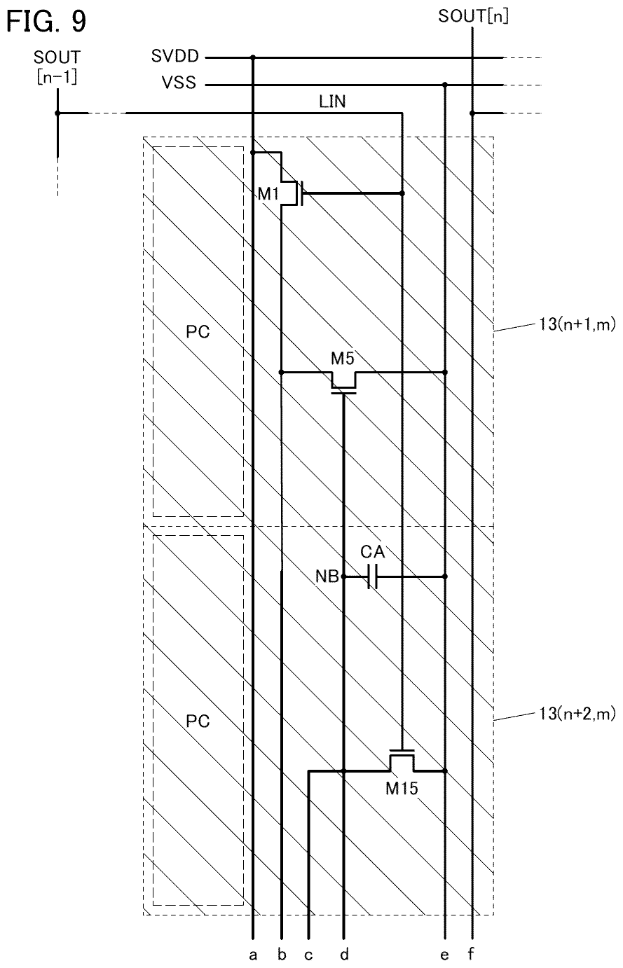

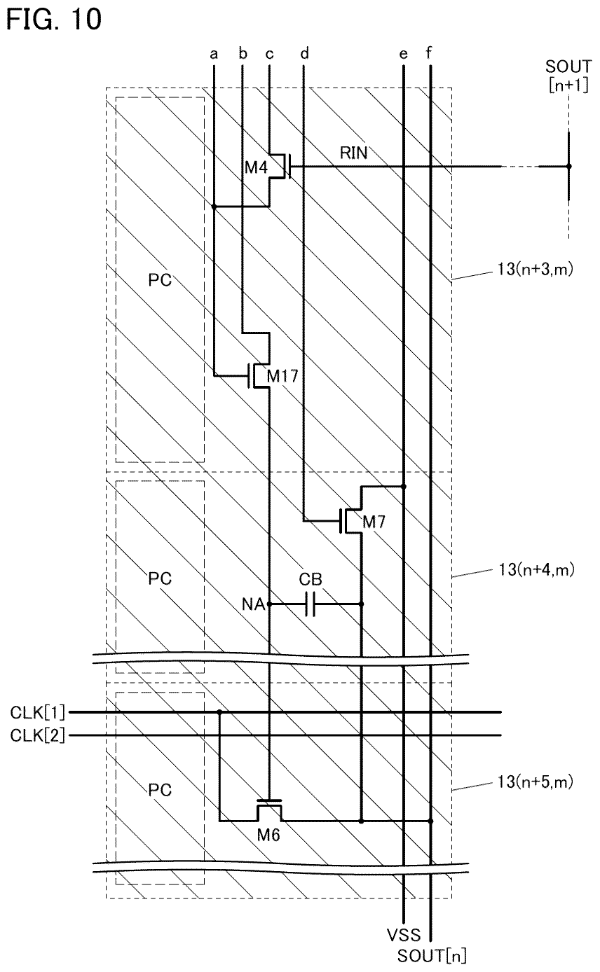

FIG. 9 and FIG. 10 are diagrams illustrating an example in which components of the shift register circuit SR illustrated in FIG. 5A, which is part of the source driver circuit SD, are distributed in a plurality of pixels 13 in the display portion 40.

FIG. 9 illustrates pixels 13(n+1,m) and 13(n+2,m) in the m-th column as an example of the pixels 13 arranged in the region 30 illustrated in FIG. 1A and FIG. 1B. FIG. 10 illustrates pixels 13(n+3,m) to 13(n+5,m) as an example. Note that FIG. 9 and FIG. 10 illustrate a sequential structure, in which at end portions of wirings, letters a to f are added to represent the same wirings.

The pixels 13(n+1,m) to 13(n+5,m) each include the pixel circuit PC. The pixel circuit PC is a circuit for driving a display element for performing display.

Furthermore, the pixels 13(n+1,m) to 13(n+5,m+8) can each include one or more components (transistors or capacitors) of the shift register circuit SR. For example, although FIG. 9 and FIG. 10 illustrate an example in which one or two components are provided in one pixel 13, three or more components may be provided. To avoid interfering with the arrangement of the pixel circuit PC, the number of components of the shift register circuit SR provided in one pixel 13 is preferably one or two.

Furthermore, any of the pixels 13(n+1,m) to 13(n+5,m) may be a pixel in which no component of the shift register circuit SR is placed. Although FIG. 9 and FIG. 10 illustrate an example in which components of one shift register circuit SR are distributed in five pixels 13, one embodiment of the present invention is not limited thereto, and the components may be distributed in four or fewer pixels 13 or six or more pixels 13.

The positional relation between the components included in the pixel circuit PC and the components of the shift register circuit SR is any positional relation, and the components can be placed in a way that facilitates easy layout. The pixel circuit PC and the shift register circuit SR may be electrically connected to a common power supply line or the like.

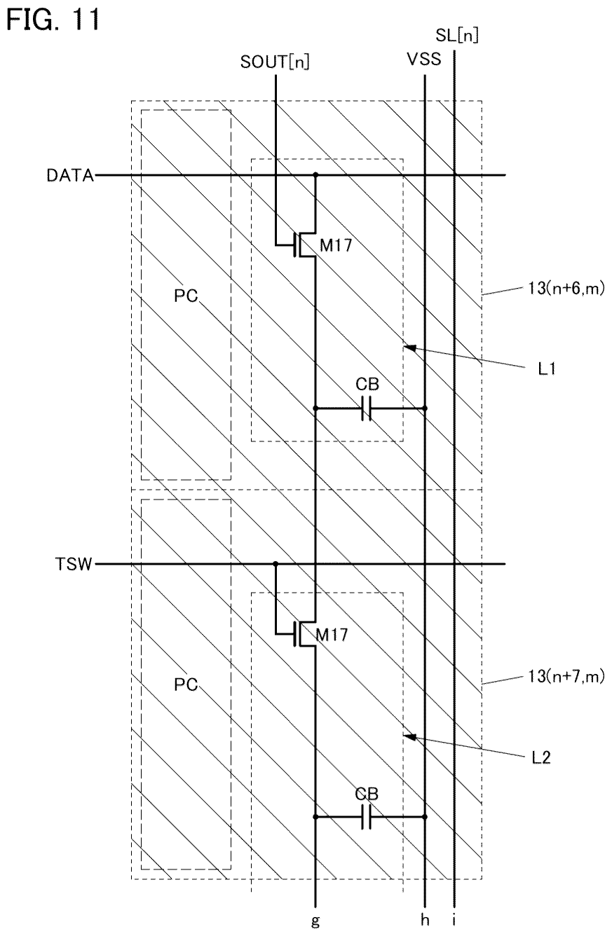

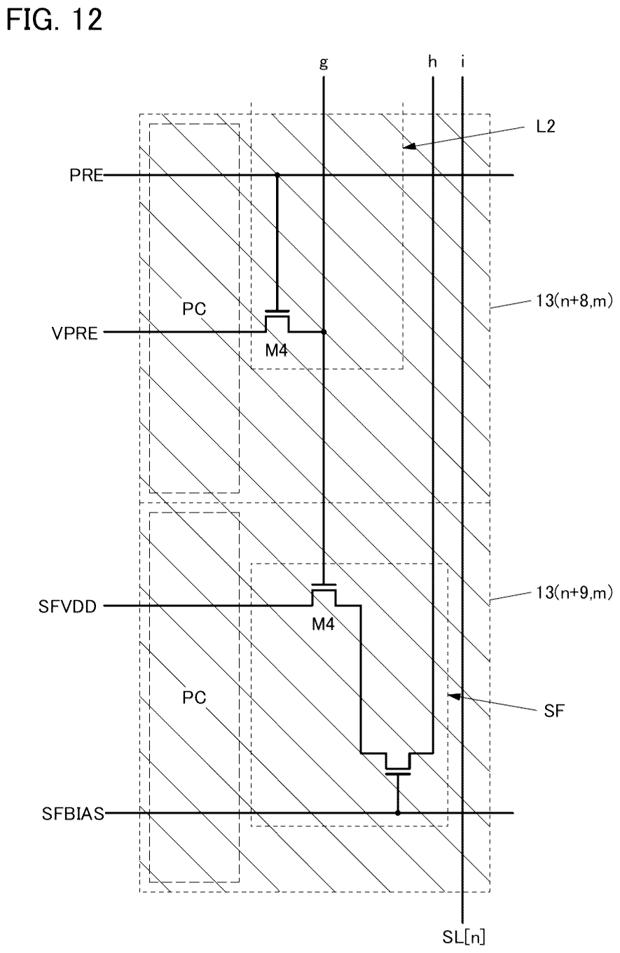

FIG. 11 and FIG. 12 are diagrams illustrating an example in which components of the latch circuit L1, the latch circuit L2, and the source follower circuit SF illustrated in FIG. 7, which are parts of the source driver circuit SD, are distributed in a plurality of pixels 13 in the display portion 40.

FIG. 11 illustrates pixels 13(n+6,m) and 13(n+7,m) in the m-th column as an example of the pixels 13 arranged in the region 30 illustrated in FIG. 1A and FIG. 1B. FIG. 12 illustrates pixels 13(n+8,m) and 13(n+9,m) as an example. Note that FIG. 11 and FIG. 12 illustrate a sequential structure, in which at end portions of wirings, letters g to i are added to represent the same wirings.

The pixels 13(n+6,m) to 13(n+9,m) each include the pixel circuit PC. The pixel circuit PC is a circuit for driving a display element for performing display.

Furthermore, the pixel 13(n+6, m) can include one or more of transistors and capacitors that are components of the latch circuit L1. The pixels 13(n+7, m) and 13(n+8, m) can each include one or more of transistors and capacitors that are components of the latch circuit L2. The pixel 13(n+9, m) can include one or more transistors that are components of the source follower circuit SF.

For example, although FIG. 11 and FIG. 12 illustrate an example in which one or two components are provided in one pixel 13, three or more components may be provided. To avoid interfering with the arrangement of the pixel circuit PC, the number of transistors and capacitors, which are components of the latch circuit L1, the latch circuit L2, and the source follower circuit SF provided in one pixel 13 is preferably one or two. Note that one pixel 13 may include components of different circuits.

In addition, any of the pixels 13(n+6,m) to 13(n+9,m) may be a pixel in which neither transistors nor capacitors, which are components of the latch circuit L1, the latch circuit L2, and the source follower circuit SF, are placed. Although FIG. 11 and FIG. 12 illustrate an example in which components of the latch circuit L1, the latch circuit L2, and the source follower circuit SF are distributed in four pixels 13, one embodiment of the present invention is not limited thereto, and the components may be distributed in three or fewer pixels 13 or five or more pixels 13.

The positional relation between the components included in the pixel circuit PC and the transistors and the capacitors, which are components of the latch circuit L1, the latch circuit L2, and the source follower circuit SF, can be any positional relation, and the components can be placed in a way that facilitates easy layout. The pixel circuit PC, the latch circuit L1, the latch circuit L2, and the source follower circuit SF may be electrically connected to a common power supply line or the like.

By distributing the components of the driver circuit in the display portion in this manner, the display device can have a narrow bezel and a high degree of freedom in the external shape.

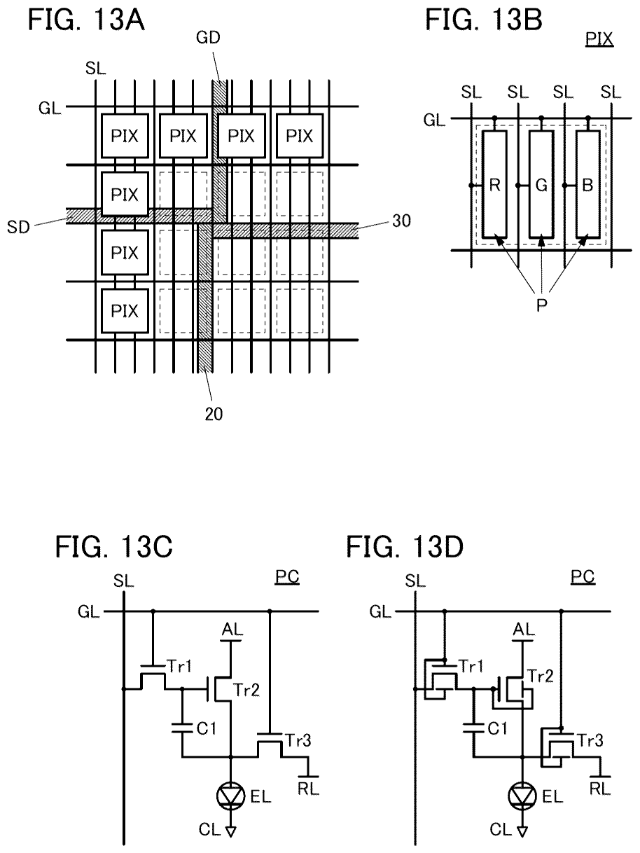

FIG. 13A is a diagram simply illustrating arrangement of some pixels PIX electrically connected to the gate line GL and the source line SL in the display device of one embodiment of the present invention. FIG. 13B is an enlarged view of the pixel PIX.

The pixel PIX includes three pixels P, for example, and the three pixels P are electrically connected to a common gate line GL, and the three pixels P are electrically connected to different source lines SL. The three pixels P have a function of exhibiting different emission colors such as red (R), green (G), and blue (B). That is, the pixels P each have a function of a subpixel to generate light of a variety of colors. Note that the pixels P correspond to the pixels 11, 12, and 13 described above.

FIG. 13C illustrates an example of the pixel circuit PC usable in the pixel P. The pixel circuit PC includes a transistor Tr1, a transistor Tr2, a transistor Tr3, a capacitor C1, and a light-emitting device EL. The gate line GL and the source line SL are electrically connected to the pixel circuit PC.

A gate of the transistor Tr1 is electrically connected to the gate line GL, one of a source and a drain of the transistor Tr1 is electrically connected to the source line SL, and the other of the source and the drain of the transistor Tr1 is electrically connected to one electrode of the capacitor Cl and a gate of the transistor Tr2. One of a source and a drain of the transistor Tr2 is electrically connected to a wiring AL, and the other of the source and the drain of the transistor Tr2 is electrically connected to one electrode of the light-emitting device EL, the other electrode of the capacitor C1, and one of a source and a drain of the transistor Tr3. A gate of the transistor Tr3 is electrically connected to the gate line GL, and the other of the source and the drain of the transistor Tr3 is electrically connected to a wiring RL. The other electrode of the light-emitting device EL is electrically connected to a wiring CL.

A data potential is supplied to the source line SL. A selection signal is supplied to the gate line GL. The selection signal includes a potential for bringing a transistor into an on state and a potential for bringing a transistor into an off state.

A reset potential is supplied to the wiring RL. An anode potential is supplied to the wiring AL. A cathode potential is supplied to the wiring CL. Here, the anode potential is a potential higher than the cathode potential. The reset potential supplied to the wiring RL can be set such that the potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistors Tr1 and Tr3 function as switches. The transistor Tr2 functions as a transistor for controlling current flowing through the light-emitting device EL. For example, it can be said that the transistor Tr1 functions as a selection transistor and the transistor Tr2 functions as a driving transistor.

Here, a transistor including a metal oxide in its channel formation region (hereinafter, referred to as an OS transistor) can be used as each of the transistors Tr1 to Tr3. Alternatively, a transistor including silicon (single crystal silicon, polycrystalline silicon, microcrystalline silicon, or amorphous silicon) in its channel formation region (hereinafter, referred to as a Si transistor) can be used as all of the transistors Tr1 to Tr3. Alternatively, OS transistors can be used as the transistors Tr1 and Tr3, and a Si transistor can be used as the transistor Tr2.

Si transistors can be used as one or more of a plurality of transistors included in the driver circuits and OS transistors can be used as the other transistors. One or more of the driver circuits can be formed using Si transistors and the others can be formed using OS transistors.

As the OS transistor, a transistor including an oxide semiconductor in its semiconductor layer where a channel is formed can be used. A semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Alternatively, it is preferable to use an oxide containing indium, gallium, tin, and zinc. Alternatively, it is preferable to use an oxide containing indium and zinc. Alternatively, it is preferable to use an oxide containing indium and gallium.

A transistor including an oxide semiconductor having a wider band gap and a lower carrier concentration than silicon can achieve an extremely low off-state current. Thus, such a low off-state current enables long-term retention of electric charge accumulated in a capacitor that is connected to the transistor in series. Hence, it is particularly preferable to use a transistor including an oxide semiconductor as each of the transistors Tr1 and Tr3 that is connected to the capacitor C1 in series. The use of the transistor including an oxide semiconductor as each of the transistors Tr1 and Tr3 can prevent leakage of electric charge retained in the capacitor C1 through the transistor Tr1 or Tr3. Furthermore, since charge retained in the capacitor C1 can be retained for a long time, a still image can be displayed for a long period without rewriting data in the pixel.

Although n-channel transistors are illustrated as the transistors in FIG. 13C, p-channel transistors can also be used.

A transistor including a pair of gates overlapping with a semiconductor layer therebetween can be used as the transistor included in the pixel circuit PC.

In the transistor including a pair of gates, the same potential is supplied to the pair of gates electrically connected to each other, whereby the on-state current of the transistor can be increased and the saturation characteristics can be improved advantageously. A potential for controlling the threshold voltage of the transistor can be supplied to one of the pair of gates. Furthermore, when a constant potential is supplied to one of the pair of gates, the stability of the electrical characteristics of the transistor can be improved. For example, one of the gates of the transistor can be electrically connected to a wiring to which a constant potential is supplied. Alternatively, one of the gates of the transistor can be electrically connected to its source or drain.

The pixel circuit PC illustrated in FIG. 13D is an example where transistors each including a pair of gates are used as the transistors Tr1 and Tr3. The pair of gates are electrically connected to each other in each of the transistors Tr1 and Tr3. Such a structure makes it possible to shorten the period in which data is written to the pixel circuit PC.

Note that the display device including the driver circuit in the display portion 40 can have a mode other than the example illustrated in FIG. 1A.

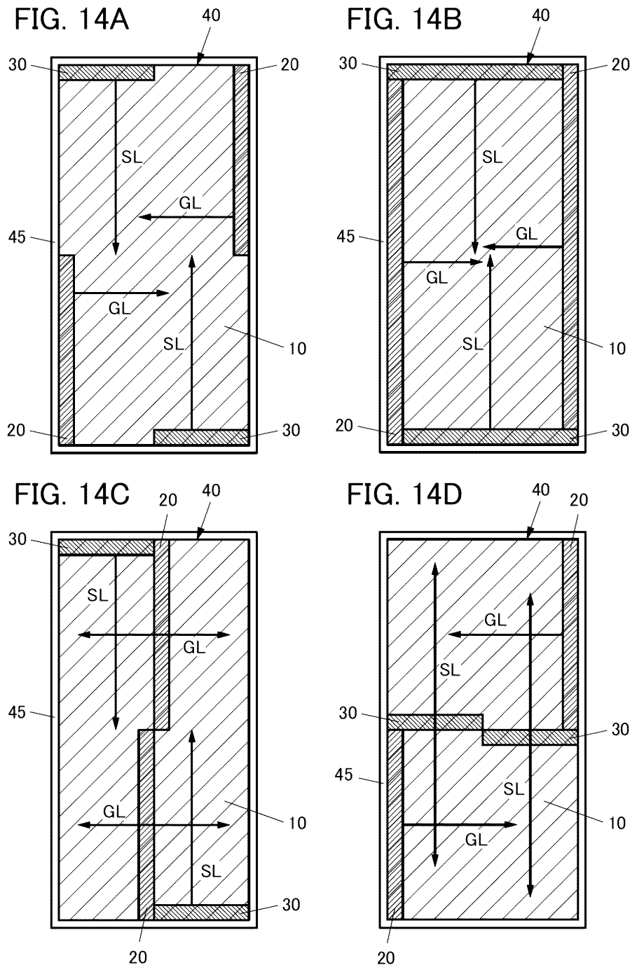

For example, as illustrated in plan views of FIG. 14A and FIG. 14B, the driver circuit can be provided at an end portion of the display portion 40. FIG. 14A illustrates an example in which the region 20 is divided vertically and the region 30 is divided horizontally as in FIG. 1A.

FIG. 14B illustrates an example in which driver circuits are provided on one side of the display portion 40 and the opposite side thereto. With such a structure, both a selection signal and a data signal can be input and thus high-speed operation is possible.

As illustrated in FIG. 14C, the region 20 can be provided to cross the display portion 40 vertically, and the region 30 can be provided at an end portion of the display portion. As illustrated in FIG. 14C, the region 30 can be provided to cross the display portion 40 horizontally, and the region 20 can be provided at an end portion of the display portion 40.

In the case where the driver circuits are distributed in the pixels of the display portion 40, unintended parasitic capacitance or the like might affect the display quality of the pixels around the driver circuits. In such a case, it is preferable that all or some of the driver circuits be placed in the peripheral portion of the display portion 40 as illustrated in FIG. 14A to FIG. 14D so that a difference in display quality is less likely to be visually perceived.

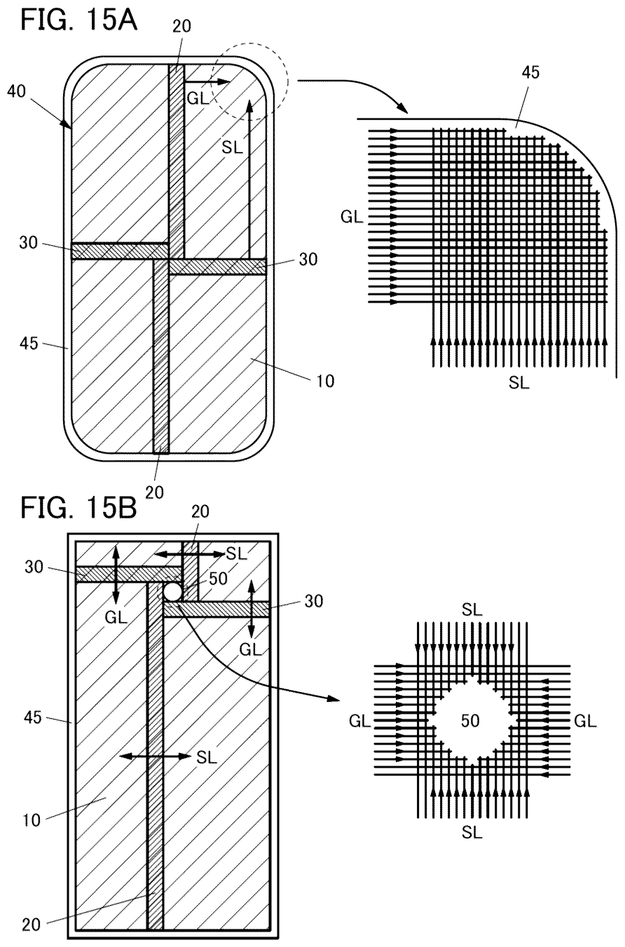

In addition, providing the driver circuit in the display portion 40 contributes not only to a narrower bezel but also to an increase in the degree of freedom of the external shape of the display device. For example, FIG. 15A illustrates an example of design in which the corner portion of the display portion 40 has curvature, and an enlarged view of the corner portion is illustrated on the right side. Note that since the pixels are rectangular, strictly speaking, the pixels are provided along a curved line at the corner portion of the display portion 40.

By providing the driver circuits in the display portion 40, a selection signal is output from the gate line GL and a data signal is output from the source line SL, from the inside of the display portion 40 toward the end portion. Accordingly, the shape of the end portion of the display portion 40 is not limited, and it is not necessary to place a driver circuit and a wiring in the bezel portion; thus, a narrow bezel can be achieved. Consequently, the degree of freedom in the external shape of the display device can be increased.

One embodiment of the present invention can also be applied to the case where a punch hole (opening portion) is provided in the display portion 40. For example, as illustrated in FIG. 15B, the region 20 and the region 30 can be provided to sandwich a punch hole 50 provided in the display portion 40. As another structure, the structure illustrated in FIG. 14B can be used, for example.

As illustrated in an enlarged view of the vicinity of the punch hole 50 on the right side of FIG. 15B, a selection signal is output from the gate line GL and a data signal is output from the source line SL, toward the punch hole. Thus, an image can be displayed even around the punch hole 50.

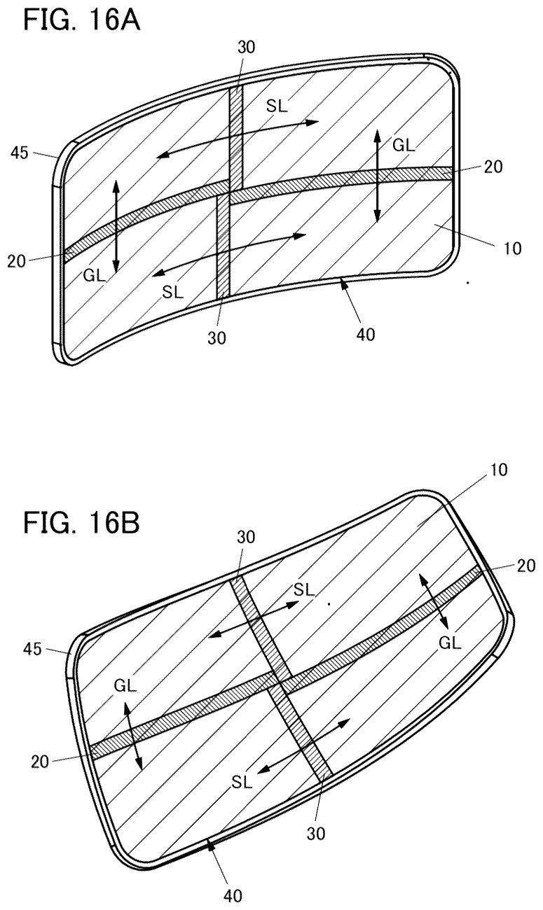

One embodiment of the present invention is also effective in the case where the display portion 40 has a curved surface. For example, a structure in which the display portion 40 has curvature in the direction where the gate line GL or the source line extends as illustrated in FIG. 16A or a structure in which a twist is applied to the display portion 40 as illustrated in FIG. 16B can be given as an example.

Note that the curved surface of the display portion 40 may be fixed or can be changed in shape in the state of the product. That is, the display device of one embodiment of the present invention can be used as a curved display or a foldable display.

In the mode illustrated in FIG. 16A and FIG. 16B, it is difficult to mount an IC chip in a bezel region having curvature. The IC chip can be mounted using a chip on film (COF) or the like; however, it is difficult to bend freely a film substrate connected to a region with curvature, and thus the bezel of the display device becomes large.

While a monolithic type driver circuit can be provided in a bezel region with curvature, the display device of one embodiment of the present invention in which the driver circuit is provided in the display portion 40 can have a narrower bezel.

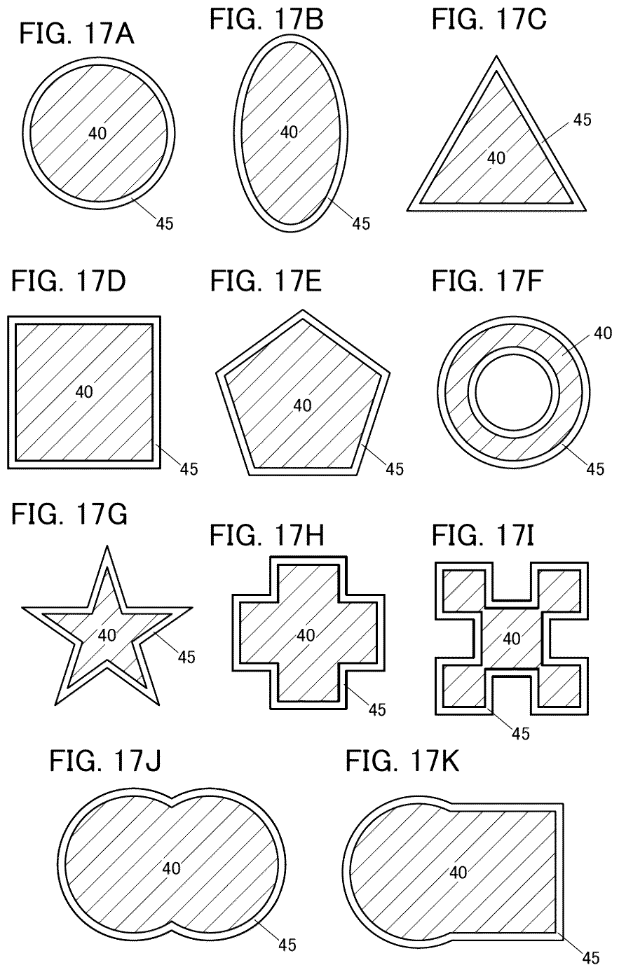

The display device of one embodiment of the present invention can have high degree of freedom in the external shape of the display portion and can be formed with a narrow bezel; thus, the external shape of the display portion 40 can be a circular shape, an elliptical shape (including an oval), a polygonal shape such as a triangle, a quadrilateral shape (including a rectangle, a rhombus, and a square), or a pentagonal shape, or a polygonal shape with rounded corners, a donut shape, a star shape, or the like, as illustrated in FIG. 17A to FIG. 17K. Furthermore, a shape obtained by a combination of two or more of the above-described shapes can be employed. Note that the polygon may be a concave polygon (a polygon with at least one interior angle greater than 180°) or a convex polygon (a polygon with all interior angles less than or equal to 180°).

At least part of this embodiment can be implemented in combination with any of the other embodiments described in this specification as appropriate.

### Embodiment 2

In this embodiment, structure examples of a display panel that can be employed for the display device according to one embodiment of the present invention will be described.

One embodiment of the present invention is a display panel including light-emitting elements (also referred to as light-emitting devices) as display elements. The display panel includes two or more pixels of different emission colors. The pixels each include a light-emitting element. The light-emitting element includes a pair of electrodes and an EL layer therebetween. The light-emitting element is preferably an organic EL element (an organic electroluminescent element). Two or more light-emitting elements of different emission colors include EL layers including different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) including light-emitting materials each need to be formed in an island shape. In the case of separately forming a part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high definition and a high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, a high resolution, or a high definition, a manufacturing yield might be reduced because of low dimensional accuracy of the metal mask and deformation due to heat or the like. Thus, a measure has been taken for a pseudo increase in definition (also referred to as pixel density) by employing unique pixel arrangement such as PenTile arrangement.

Note that in this specification and the like, the term “island shape” refers to a state where two or more layers formed using the same material in the same step are physically separated from each other. For example, the term “island-shaped light-emitting layers” refers to a state where a light-emitting layer and an adjacent light-emitting layer are physically separated from each other.

In one embodiment of the present invention, fine patterning of EL layers is performed by a photolithography method without using a shadow mask such as a fine metal mask (an FMM). Accordingly, it is possible to achieve a high-definition display panel with a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, a part or the whole of the EL layer can be physically divided from each other. This can inhibit leakage current flowing between adjacent light-emitting elements through a layer (also referred to as a common layer) shared by the light-emitting elements. Thus, it is possible to prevent light emission due to unintended crosstalk, so that a display panel with extremely high contrast can be achieved. In particular, a display panel having high current efficiency at low luminance can be achieved.

Note that in one embodiment of the present invention, the display panel can be also obtained by combining a light-emitting element that emits the white light with a color filter. In that case, light-emitting elements having the same structure can be used as light-emitting elements provided in pixels (subpixels) that emit light of different colors, which allows all the layers to be common layers. In addition, a part or the whole of the EL layer may be divided from each other by a photolithography process. Thus, leakage current through the common layer is inhibited; accordingly, a high-contrast display panel can be achieved. In particular, when an element has a tandem structure where a plurality of light-emitting layers are stacked with a highly conductive intermediate layer therebetween, leakage current through the intermediate layer can be effectively prevented, so that a display panel with high luminance, high definition, and high contrast can be achieved.

In the case where the EL layer is processed by a photolithography method, part of the light-emitting layer is sometimes exposed to cause degradation. Thus, an insulating layer covering at least the side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display panel.

Moreover, between two adjacent light-emitting elements, there is a region (a concave portion) where none of the EL layers of the light-emitting elements is provided. In the case where a common electrode or a common electrode and a common layer is/are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap positioned between the two adjacent light-emitting elements is preferably filled with a resin layer (also referred to as local filling planarization, or LFP) functioning as a planarization film. The resin layer has a function of a planarization film. This structure can inhibit disconnection of the common layer or the common electrode and can provide a highly reliable display panel.

More specific structure examples of the display panel according to one embodiment of the present invention will be described below with reference to drawings.

### Structure Example 1

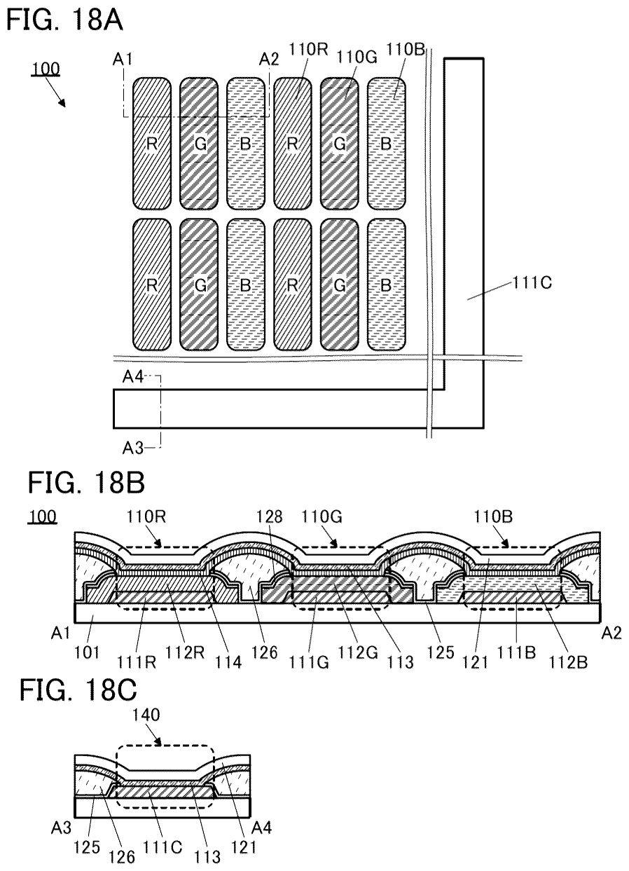

FIG. 18A is a schematic top view illustrating a display panel 100 according to one embodiment of the present invention. The display panel 100 includes, over a substrate 101, a plurality of light-emitting elements 110R exhibiting red, a plurality of light-emitting elements 110G exhibiting green, and a plurality of light-emitting elements 110B exhibiting blue. In FIG. 18A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 18A illustrates what is called stripe arrangement, in which the light-emitting elements of the same color are arranged in one direction. Note that the arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can be also employed.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As the light-emitting substance contained in the EL element, not only an organic compound but also an inorganic compound (a quantum dot material or the like) can be used.

FIG. 18A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the periphery of the display region. For example, the connection electrode 111C may be provided along one side of the periphery of the display region, or may be provided along two or more sides of the periphery of the display region. That is, in the case where the display region has a rectangular top surface shape, the top surface shape of the connection electrode 111C can be a band shape (a rectangle), an L shape, a U shape (a square bracket shape), a quadrilateral shape, or the like. Note that in this specification and the like, a top surface shape refers to a shape in a plan view, i.e., a shape seen from above.

FIG. 18B and FIG. 18C are schematic cross-sectional views corresponding to the dashed-dotted line A1-A2 and the dashed-dotted line A3-A4, respectively, in FIG. 18A. FIG. 18B is a schematic cross-sectional view illustrating the light-emitting element 110R, the light-emitting element 110G, and the light-emitting element 110B, and FIG. 18C is a schematic cross-sectional view illustrating a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can be also referred to as an EL layer and includes at least a layer containing a light-emitting substance (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

Each of the organic layer 112 and the common layer 114 can independently include one or more of an electron-injection layer, an electron-transport layer, a hole-injection layer, and a hole-transport layer. For example, it is possible to employ a structure where the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a light-transmitting property with respect to visible light is used for one of the pixel electrodes and the common electrode 113, and a conductive film having a reflective property is used for the other. When the pixel electrodes have light-transmitting properties and the common electrode 113 has a reflective property, a bottom-emission display panel can be obtained. In contrast, when the pixel electrodes have reflective properties and the common electrode 113 has a light-transmitting property, a top-emission display panel can be obtained. Note that when both the pixel electrodes and the common electrode 113 have light-transmitting properties, a dual-emission display panel can be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a foreign material (for example, also referred to as dust or particles) in a manufacturing step is easily removed by processing such as cleaning, which is preferable.

Note that in this specification and the like, a tapered shape indicates a shape in which at least part of a side surface of a component is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between the top surface and the side surface of an end portion of the organic layer 112 is approximately 90°. In contrast, an organic film formed using an FMM (Fine Metal Mask) or the like tends to be gradually thinner towards its end portion, and has a sloped top surface in the range greater than or equal to 1 μm and less than or equal to 10 μm from an end portion, for example; thus, a shape whose top surface and side surface are difficult to distinguish from each other is formed.

An insulating layer 125, a resin layer 126, and a layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to fill regions between end portions of the organic layers 112 and between the two organic layers 112. The resin layer 126 has a top surface with a smooth convex shape, and the common layer 114 and the common electrode 113 are provided to cover the top surface of the resin layer 126.

The resin layer 126 functions as a planarization film that fills a gap positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved in an organic solvent or the like used at the time of forming the resin layer 126. Therefore, the insulating layer 125 is provided between the organic layer 112 and the resin layer 126 to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD (Atomic Layer Deposition) method is used for the insulating layer 125, the insulating layer 125 having few pinholes and an excellent function of protecting the EL layer can be formed.

Note that in this specification and the like, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method enabling good coverage.

In addition, a structure may be employed in which a reflective film (e.g., a metal film including one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has few pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, it is preferable that the organic insulating film function as a planarization film. This enables the top surface of the organic insulating film to be flat, which results in improved coverage with the inorganic insulating film thereover and a higher barrier property. Moreover, the top surface of the protective layer 121 is flat, which is preferable because the influence of an uneven shape due to a lower component can be reduced in the case where a component (e.g., a color filter, an electrode of a touch sensor, a lens array, or the like) is provided above the protective layer 121.

FIG. 18C illustrates the connection portion 140 where the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 18C illustrates the connection portion 140 where the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display panel whose structure is partly different from that of Structure Example 1 is described below. Note that the above description can be referred to for portions common to those in Structure Example 1, and the description is omitted in some cases.

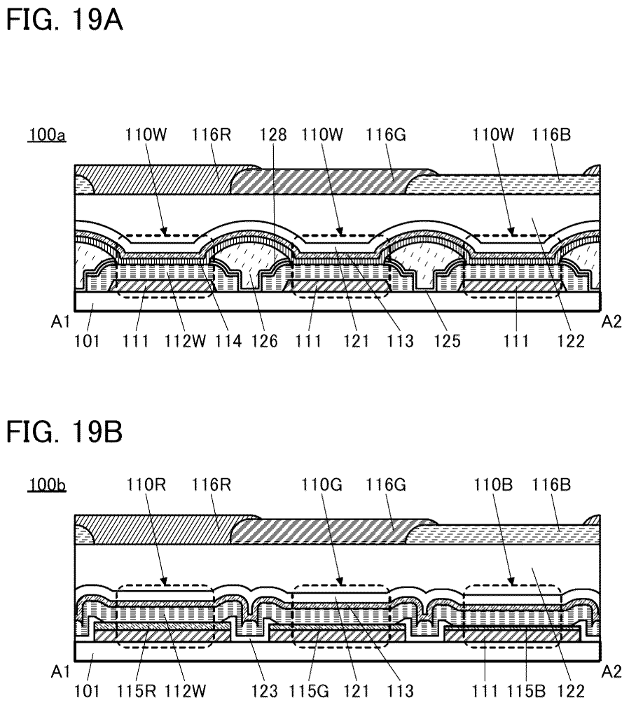

FIG. 19A is a schematic cross-sectional view of a display panel 100a. The display panel 100a is different from the display panel 100 mainly in the structure of the light-emitting element and including a coloring layer.

The display panel 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can include two or more kinds of light-emitting materials whose emission colors are complementary colors. For example, the organic layer 112W can include a light-emitting organic compound that emits red light, a light-emitting organic compound that emits green light, and a light-emitting organic compound that emits blue light. In addition, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display panel can have high contrast and high color reproducibility.

An insulating layer 122 that functions as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 serves as a formation surface over which the coloring layer 116R, the coloring layer 116G, and the coloring layer 116B are formed; thus, owing to the flat top surface of the insulating layer 122, the thickness of the coloring layer 116R or the like can be uniform and color purity can be increased. Note that when the thickness of the coloring layer 116R or the like is non-uniform, the amount of light absorption varies from place to place in the coloring layer 116R, which might decrease the color purity.

### Structure Example 3

FIG. 19B is a schematic cross-sectional view illustrating a display panel 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having both a visible-light reflecting property and a visible-light transmitting property is used for the common electrode 113, so that a micro resonator (microcavity) structure can be achieved. In that case, by adjusting the thicknesses of the conductive layer 115R, the conductive layer 115G, and the conductive layer 115B to optimal optical path lengths, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

In addition, an insulating layer 123 that covers end portions of the pixel electrode 111, the conductive layer 115R, the conductive layer 115G, and the conductive layer 115B is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display panel can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Accordingly, generation of leakage current between adjacent light-emitting elements through the organic layer 112W can be inhibited without processing the organic layer 112W by a photolithography method or the like.

The above is the description of the structure example of the display panel.

### Pixel Layout

A pixel layout different from that in FIG. 18A will be mainly described below. There is no particular limitation on the arrangement of light-emitting elements (subpixels), and a variety of methods can be employed.

Examples of the top surface shape of the subpixel include polygons such as a triangle, a quadrilateral (including a rectangle and a square), and a pentagon; polygons with rounded corners; an ellipse; and a circle. Here, the top surface shape of the subpixel corresponds to the top surface shape of a light-emitting region of the light-emitting element.

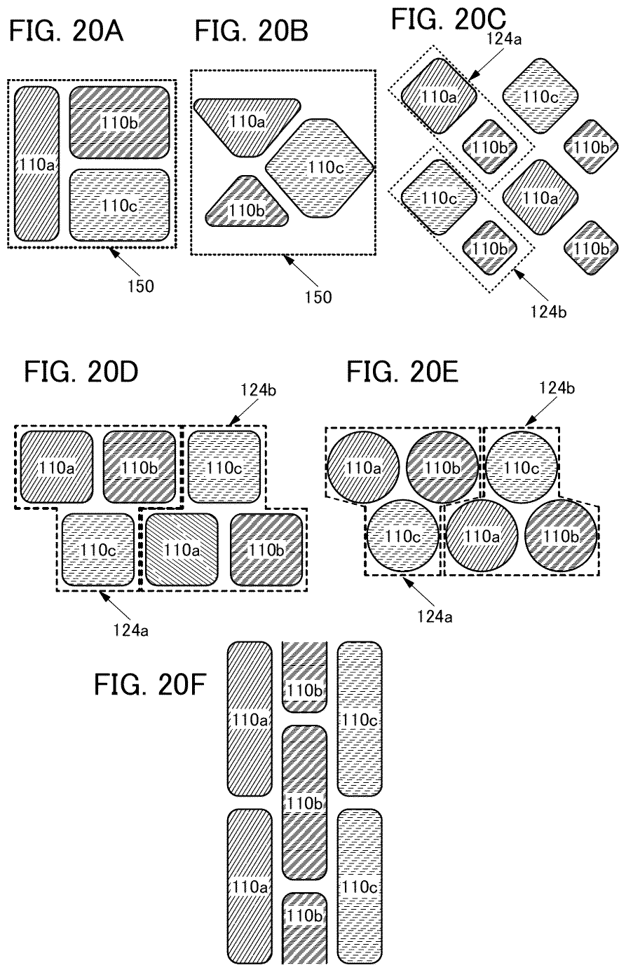

A pixel 150 illustrated in FIG. 20A employs S-stripe arrangement. The pixel 150 illustrated in FIG. 20A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 20B includes the light-emitting element 110a whose top surface has a rough trapezoidal or rough triangle shape with rounded corners, the light-emitting element 110b whose top surface has a rough trapezoidal or rough triangle shape with rounded corners, and the light-emitting element 110c whose top surface has a rough quadrilateral or rough hexagonal shape with rounded corners. In addition, the light-emitting element 110a has a larger light-emitting area than the light-emitting element 110b. In this manner, the shapes and sizes of the light-emitting elements can be independently determined. For example, the size of a light-emitting element with higher reliability can be made smaller. For example, the light-emitting element 110a may be a green-light-emitting element, the light-emitting element 110b may be a red-light-emitting element, and the light-emitting element 110c may be a blue-light-emitting element.

PenTile arrangement is employed for pixels 124a and 124b illustrated in FIG. 20C. FIG. 20C illustrates an example where the pixels 124a each including the light-emitting element 110a and the light-emitting element 110b and the pixels 124b each including the light-emitting element 110b and the light-emitting element 110c are alternately arranged. For example, the light-emitting element 110a may be a red-light-emitting element, the light-emitting element 110b may be a green-light-emitting element, and the light-emitting element 110c may be a blue-light-emitting element.

Delta arrangement is employed for the pixels 124a and 124b illustrated in FIG. 20D and FIG. 20E. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red-light-emitting element, the light-emitting element 110b may be a green-light-emitting element, and the light-emitting element 110c may be a blue-light-emitting element.

FIG. 20D illustrates an example where the top surface of each light-emitting element has a rough quadrilateral shape with rounded corners, and FIG. 20E illustrates an example where the top surface of each light-emitting element has a circular shape.

FIG. 20F illustrates an example where light-emitting elements of different colors are arranged in a zigzag manner. Specifically, the positions of top sides of two light-emitting elements arranged in a row direction (e.g., the light-emitting element 110a and the light-emitting element 110b or the light-emitting element 110b and the light-emitting element 110c) are not aligned in a top view. For example, the light-emitting element 110a may be a red-light-emitting element, the light-emitting element 110b may be a green-light-emitting element, and the light-emitting element 110c may be a blue-light-emitting element.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer has a polygonal shape with rounded corners, an elliptical shape, a circular shape, or the like in some cases. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in combination with any of the other embodiments described in this specification as appropriate.

### Embodiment 3

In this embodiment, vertical transistors that can be used in the driver circuit described in Embodiment 1 will be described. The vertical transistor has a structure that enables downsizing and high-speed operation. Note that a vertical transistor can also be used in a pixel circuit.

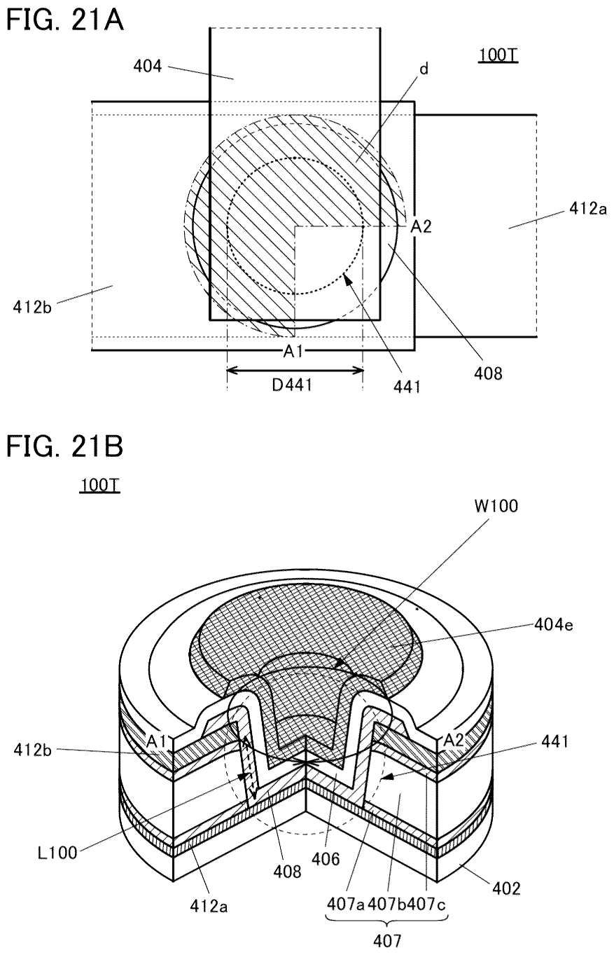

FIG. 21A and FIG. 21B are diagrams illustrating a vertical transistor. FIG. 21A is a plan view. FIG. 21B is a cross-sectional perspective view along A1-A2 in the depth direction of a region d illustrated in FIG. 21A. Note that for simplification, some components are not illustrated in FIG. 21A and FIG. 21B.

A transistor 100T, which is a vertical transistor, can be provided over a substrate 402. The transistor 100T includes a conductive layer 404, a conductive layer 404e, an insulating layer 406, a semiconductor layer 408, a conductive layer 412a, and a conductive layer 412b. The conductive layer 404 is a gate line electrically connected to the conductive layer 404e functioning as a gate electrode. Part of the insulating layer 406 functions as a gate insulating layer. The conductive layer 412a functions as one of a source electrode and a drain electrode. The conductive layer 412b functions as the other of the source electrode and the drain electrode.

The conductive layer 412a is provided over the substrate 402, an insulating layer 407 is provided over the conductive layer 412a, and the conductive layer 412b is provided over the insulating layer 407. The insulating layer 407 includes a region interposed between the conductive layer 412a and the conductive layer 412b. The conductive layer 412a includes a region overlapping with the conductive layer 412b with the insulating layer 407 therebetween. An opening 441 reaching the conductive layer 412a is provided in the insulating layer 407 and the conductive layer 412b.

Although the conductive layer 412a and the conductive layer 412b each having a single-layer structure are illustrated in FIG. 21B, one embodiment of the present invention is not limited thereto. The conductive layer 412a and the conductive layer 412b can each have a stacked-layer structure.

The top surface shape of the opening 441 can be a circle or an ellipse, for example. When the top surface shape of the opening 441 is a circle, the processing accuracy for forming the opening 441 can be increased and thus the opening 441 having a minute size can be formed. Note that the top surface shape of the opening 441 may also be a polygon such as a triangle, a quadrilateral (including a rectangle, a rhombus, and a square), or a pentagon, or a polygon with rounded corners. The opening 441 can be formed using a resist mask, for example.

The semiconductor layer 408 is provided to cover the opening 441. The semiconductor layer 408 includes a region in contact with a top surface and a side surface of the conductive layer 412b, a side surface of the insulating layer 407, and a top surface of the conductive layer 412a. The semiconductor layer 408 is electrically connected to the conductive layer 412a through the opening 441. The semiconductor layer 408 has a shape along the shapes of the top surface and the side surface of the conductive layer 412b, the side surface of the insulating layer 407, and the top surface of the conductive layer 412a.

In the semiconductor layer 408 provided along the side surface of the insulating layer 407, between the source electrode and the drain electrode, the entire region overlapping with the gate electrode with the gate insulating layer therebetween functions as a channel formation region. In the semiconductor layer 408, a region in contact with the source electrode functions as a source region, and a region in contact with the drain electrode functions as a drain region.

Although the semiconductor layer 408 has a single-layer structure in FIG. 21B and the like, one embodiment of the present invention is not limited thereto. The semiconductor layer 408 can have a stacked structure of two or more layers.

The insulating layer 406 functioning as the gate insulating layer of the transistor 100T is provided over the semiconductor layer 408, the conductive layer 412b, and the insulating layer 407 to cover a depressed portion originating from the opening 441.

The conductive layer 404e of the transistor 100T is provided over the insulating layer 406 to cover the depressed portion originating from the opening 441. Here, an insulating layer (not illustrated) is preferably provided over the conductive layer 404e and the insulating layer 406. An opening reaching the conductive layer 404e is formed in the insulating layer and the conductive layer 404 functioning as a gate line is electrically connected to the conductive layer 404e in the opening.

The conductive layer 404e includes a region overlapping with the semiconductor layer 408 with the insulating layer 406 therebetween in the opening 441. The conductive layer 404e also includes a region overlapping with the conductive layer 412a and a region overlapping with the conductive layer 412b with the insulating layer 406 and the semiconductor layer 408 therebetween. The conductive layer 404e preferably covers an end portion of the conductive layer 412b on the opening 441 side.

The transistor 100T is what is called a top-gate transistor including the gate electrode above the semiconductor layer 408. Furthermore, since a bottom surface of the semiconductor layer 408 is in contact with the source electrode or the drain electrode, the transistor 100T can be referred to as a TGBC (Top Gate Bottom Contact) transistor.

The conductive layer 412a, the conductive layer 412b, and the conductive layer 404 can function as wirings, and the transistor 100T can be provided in a region where these wirings overlap with each other. That is, the areas occupied by the transistor 100T and the wirings can be reduced in the circuit including the transistor 100T and the wirings. This can reduce the area occupied by the circuit.

In the transistor of one embodiment of the present invention, the conductive layer 412a, the conductive layer 412b, and the conductive layer 404 functioning as wirings can be provided by processing different conductive films. Thus, any one of the conductive layers can be provided to overlap with at least one of the other conductive layers, leading to high layout flexibility and a reduction in the area occupied by the circuit.

Next, the channel length and the channel width of the transistor 100T will be described. In the semiconductor layer 408, a region in contact with the conductive layer 412a functions as one of the source region and the drain region, a region in contact with the conductive layer 412b functions as the other of the source region and the drain region, and a region between the source region and the drain region functions as the channel formation region.

The channel length of the transistor 100T is the distance between the source region and the drain region. In FIG. 21B, a channel length L100 of the transistor 100T is indicated by a dashed double-headed arrow. In the cross-sectional view, the channel length L100 is the distance between an end portion of the region where the semiconductor layer 408 is in contact with the conductive layer 412a and an end portion of the region where the semiconductor layer 408 is in contact with the conductive layer 412b.

That is, the channel length L100 is determined by the thickness of the insulating layer 407 and the angle formed between the side surface of the insulating layer 407 on the opening 441 side and the top surface of the conductive layer 412a, and is not affected by the performance of a light-exposure apparatus used for manufacturing the transistor. Thus, the channel length L100 can be a value smaller than that of the resolution limit of a light-exposure apparatus, which enables a transistor having a minute size.

The reduction in the channel length L100 can increase the on-state current of the transistor 100T. With use of the transistor 100T, a circuit capable of high-speed operation can be manufactured. Furthermore, the transistor can be downsized, which enables a reduction in the area occupied by the circuit.

Although FIG. 21B and the like illustrate the structure in which the side surface of the insulating layer 407 on the opening 441 side is linear in the cross-sectional view, one embodiment of the present invention is not limited thereto. In a cross-sectional view, the side surface of the insulating layer 407 on the opening 441 side can be curved. Alternatively, the side surface can include both a linear region and a curved region.

The channel width of the transistor 100T is the width of the source region or the width of the drain region in a direction orthogonal to the channel length direction. That is, the channel width is a width of a region where the semiconductor layer 408 is in contact with the conductive layer 412a or a width of a region where the semiconductor layer 408 is in contact with the conductive layer 412b in the direction orthogonal to the channel length direction. Here, the channel width of the transistor 100T is described as the width of the region where the semiconductor layer 408 is in contact with the conductive layer 412b in the direction orthogonal to the channel length direction. In FIG. 21A and FIG. 21B, a channel width W100 of the transistor 100T is indicated by a solid double-headed arrow. In the top view, the channel width W100 is the length of the end portion of the bottom surface of the conductive layer 412b on the opening 441 side.

The channel width W100 is determined by the top surface shape of the opening 441. Note that in the case where the top surface shape of the opening 441 is a circle, the channel width W100 can be calculated to be “D441x” assuming that the diameter of the opening 441 is D441 and the thickness of the conductive layer 412b is negligible.

In other words, it can be said that the transistor 100T has a large channel width with respect to its occupation area. The transistor 100T with the large channel width W100 can have a high on-state current and thus a circuit capable of high-speed operation can be manufactured.

Components included in the transistor 100T of this embodiment will be described below.

### Components of Transistor

### Semiconductor Layer 408

There is no particular limitation on a semiconductor material that can be used for the semiconductor layer 408. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials can contain impurities as dopants.

There is no particular limitation on the crystallinity of a semiconductor material used for the semiconductor layer 408, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

The semiconductor layer 408 preferably includes a metal oxide (an oxide semiconductor). Examples of the metal oxide that can be used for the semiconductor layer 408 include indium oxide, gallium oxide, and zinc oxide. The metal oxide preferably contains at least indium (In) or zinc (Zn). The metal oxide preferably contains two or three kinds selected from indium, an element M, and zinc. The element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin. The element M is further preferably gallium.

For the semiconductor layer 408, for example, any of indium oxide, indium gallium oxide (In-Ga oxide), indium zinc oxide (In-Zn oxide), indium tin oxide (In-Sn oxide), indium titanium oxide (In-Ti oxide), gallium zinc oxide (Ga-Zn oxide), indium aluminum zinc oxide (In-Al-Zn oxide, also referred to as IAZO), indium tin zinc oxide (In-Sn-Zn oxide), indium titanium zinc oxide (In-Ti-Zn oxide), indium gallium zinc oxide (In-Ga-Zn oxide, also referred to as IGZO), indium gallium tin zinc oxide (In-Ga-Sn-Zn oxide, also referred to as IGZTO), and indium gallium aluminum zinc oxide (In-Ga-Al-Zn oxide, also referred to as IGAZO or IAGZO) can be used. Alternatively, indium tin oxide containing silicon, or the like can also be used.

Here, the composition of the metal oxide included in the semiconductor layer 408 greatly affects the electrical characteristics and reliability of the transistor 100T. For example, by increasing the proportion of the number of indium atoms in the total number of atoms of all the metal elements contained in the metal oxide, a transistor having a high on-state current can be provided.

In the case of using In-Zn oxide for the semiconductor layer 408, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In-Sn oxide for the semiconductor layer 408, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In-Sn-Zn oxide for the semiconductor layer 408, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In-Al-Zn oxide for the semiconductor layer 408, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In-Ga-Zn oxide for the semiconductor layer 408, a metal oxide in which the atomic proportion of indium in the total number of atoms of all the contained metal elements is higher than the atomic proportion of gallium can be used. It is further preferable to use a metal oxide in which the atomic proportion of zinc atoms is higher than the atomic proportion of gallium atoms. For example, it is possible to use a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof for the semiconductor layer 408.

In the case of using In-M-Zn oxide for the semiconductor layer 408, a metal oxide in which the atomic proportion of indium in the total number of atoms of all the contained metal elements is higher than the atomic proportion of element M can be used. It is further preferable to use a metal oxide in which the atomic proportion of zinc is higher than the atomic proportion of the element M. For example, a metal oxide having any of the following atomic ratios of metal elements can be used for the semiconductor layer 408: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the neighborhood thereof.

A metal oxide with a higher indium content percentage enables a transistor to have a higher on-state current. By using such a transistor as a transistor requiring a high on-state current, a circuit having excellent electrical characteristics can be formed.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may also be combined for the analysis. An element with lower content percentages might show discrepancy between the actual content percentage and the content percentage obtained by analysis due to the analysis accuracy. In the case where the content percentage of the element M is low, for example, the content percentage of the element M obtained by analysis may be lower than the actual content percentage.

A composition in the neighborhood in this specification and the like includes the range of ±30 % of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

The semiconductor layer 408 may also have a stacked-layer structure including two or more metal oxide layers. The two or more metal oxide layers included in the semiconductor layer 408 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 408 can have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 408. For example, a metal oxide layer having a CAAC (c-axis aligned crystal) structure, a polycrystalline (poly-crystal) structure, a nano-crystal (nc) structure, or the like can be used. With use of a metal oxide layer having crystallinity as the semiconductor layer 408, the density of defect states in the semiconductor layer 408 can be reduced, which enables the transistor to have high reliability.

The higher the crystallinity of the metal oxide layer used as the semiconductor layer 408 is, the lower the density of defect states in the semiconductor layer 408 can be. By contrast, the use of a metal oxide layer having low crystallinity enables a transistor to flow a large amount of current. Note that the CAAC structure is a crystal structure in which a plurality of microcrystals (typically, a plurality of IGZO microcrystals) have c-axis alignment and are connected on the a-b plane without alignment. The CAAC structure has a smaller number of crystal grain boundaries, grains, and the like in the a-b plane than a polycrystalline structure does, which enables a highly reliable semiconductor device.

The semiconductor layer 408 may also have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 408 may have the same composition or substantially the same compositions. Employing a stacked-layer structure of metal oxide layers having the same composition can lead to a reduction in the manufacturing cost because, for example, the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer 408 can have different compositions.

When an oxide semiconductor is used for the semiconductor layer 408, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter, also referred to as off-state current), and electric charge accumulated in a capacitor that is connected in series to the transistor can be retained for a long period. Furthermore, the power consumption of the semiconductor device can be reduced with the OS transistor.

### Insulating Layer 407

In the case where an oxide semiconductor is used for the semiconductor layer 408, an inorganic insulating material can be suitably used for the insulating layer 407 (an insulating layer 407a, an insulating layer 407b, and an insulating layer 407c). Note that the insulating layer 407 can have a stacked-layer structure of an inorganic insulating material and an organic insulating material.

As the inorganic insulating material, one or more of an oxide, an oxynitride, a nitride oxide, and a nitride can be used. For the insulating layer 407, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

In this specification and the like, an oxynitride refers to a material that includes more oxygen than nitrogen in its composition. A nitride oxide refers to a material that includes more nitrogen than oxygen in its composition. For example, silicon oxynitride refers to a material that contains more oxygen than nitrogen in its composition, and silicon nitride oxide refers to a material that contains more nitrogen than oxygen in its composition.

It is preferable to use an oxide or an oxynitride for the insulating layer 407b. A film from which oxygen is released by heating is preferably used as the insulating layer 407b. For example, silicon oxide or silicon oxynitride can be suitably used for the insulating layer 407b.

When oxygen is released from the insulating layer 407b, oxygen can be supplied from the insulating layer 407b to the semiconductor layer 408. Supplying oxygen from the insulating layer 407b to the semiconductor layer 408, particularly to the channel formation region in the semiconductor layer 408, can reduce the number of oxygen vacancies (Vo) and VoH (defect in which hydrogen enters oxygen vacancy) in the semiconductor layer 408, so that a highly reliable transistor having favorable electrical characteristics can be obtained. The insulating layer 407b preferably has a high oxygen diffusion coefficient. When the insulating layer 407b has a high oxygen diffusion coefficient, oxygen is easily diffused in the insulating layer 407b, so that oxygen can be efficiently supplied from the insulating layer 407b to the semiconductor layer 408. Examples of treatment for supplying oxygen to the semiconductor layer 408 include heat treatment in an oxygen-containing atmosphere and plasma treatment in an oxygen-containing atmosphere.

It is preferable that the number of oxygen vacancies (Vo) and VoH be small in the channel formation region of the transistor 100T. Particularly in the case where the channel length L100 is short, oxygen vacancy (Vo) and VoH in the channel formation region greatly affect electrical characteristics and reliability. For example, diffusion of VoH from the source region or the drain region into the channel formation region increases the carrier concentration in the channel formation region, which might cause a change in the threshold voltage or a reduction in the reliability in the transistor 100T. As the channel length L100 of the transistor 100T is shorter, such diffusion of VoH more greatly affects electrical characteristics and reliability. Supplying oxygen from the insulating layer 407b to the semiconductor layer 408, particularly to the channel formation region in the semiconductor layer 408, can reduce the number of oxygen vacancies (Vo) and VoH. Thus, the transistor with a short channel length can have favorable electrical characteristics and high reliability.

The insulating layer 407a and the insulating layer 407c are preferably less likely to transmit oxygen. The insulating layer 407a and the insulating layer 407c function as blocking films that inhibit release of oxygen from the insulating layer 407b. Moreover, the insulating layer 407a and the insulating layer 407c are preferably less likely to transmit hydrogen. The insulating layer 407a and the insulating layer 407c function as blocking films that inhibit diffusion of hydrogen into the semiconductor layer 408 from the outside of the transistor through the insulating layer 407. The insulating layer 407a and the insulating layer 407c preferably have high film densities. The insulating layer 407a and the insulating layer 407c having high film densities can have a high blocking property against oxygen and hydrogen. The film densities of the insulating layer 407a and the insulating layer 407c are preferably higher than the film density of the insulating layer 407b. In the case where silicon oxide or silicon oxynitride is used for the insulating layer 407b, silicon nitride, silicon nitride oxide, or aluminum oxide can be suitably used for each of the insulating layer 407a and the insulating layer 407c, for example. The insulating layer 407a and the insulating layer 407c each preferably include a region containing more nitrogen than the insulating layer 407b. For example, a material containing more nitrogen than the insulating layer 407b can be used for each of the insulating layer 407a and the insulating layer 407c. A nitride or a nitride oxide is preferably used for each of the insulating layer 407a and the insulating layer 407c. For example, silicon nitride or silicon nitride oxide can be suitably used for each of the insulating layer 407a and the insulating layer 407c.

When oxygen contained in the insulating layer 407b is diffused upward from a region of the insulating layer 407b that is not in contact with the semiconductor layer 408 (e.g., a top surface of the insulating layer 407b), the amount of oxygen supplied from the insulating layer 407b to the semiconductor layer 408 might be reduced. Forming the insulating layer 407c over the insulating layer 407b can inhibit diffusion of oxygen contained in the insulating layer 407b from the region of the insulating layer 407 that is not in contact with the semiconductor layer 408. Similarly, forming the insulating layer 407a under the insulating layer 407b can inhibit downward diffusion of oxygen from the region of the insulating layer 407 that is not in contact with the semiconductor layer 408. Accordingly, the amount of oxygen supplied from the insulating layer 407b to the semiconductor layer 408 is increased, whereby the number of oxygen vacancies (Vo) and VoH in the semiconductor layer 408 can be reduced. Consequently, a transistor with favorable electrical characteristics and high reliability can be obtained.

The conductive layer 412a and the conductive layer 412b are oxidized by oxygen contained in the insulating layer 407b and have high resistance in some cases. Moreover, when the conductive layer 412a and the conductive layer 412b are oxidized by oxygen contained in the insulating layer 407b, the amount of oxygen supplied from the insulating layer 407b to the semiconductor layer 408 might be reduced. Forming the insulating layer 407a between the insulating layer 407b and the conductive layer 412a can inhibit the conductive layer 412a from being oxidized and having high resistance. Similarly, forming the insulating layer 407c between the insulating layer 407b and the conductive layer 412b can inhibit the conductive layer 412b from being oxidized and having high resistance. In addition, the amount of oxygen supplied from the insulating layer 407b to the semiconductor layer 408 is increased and the number of oxygen vacancies (Vo) and VoH in the semiconductor layer 408 can be reduced, whereby the transistor can have favorable electric characteristics and high reliability.

Hydrogen diffused in the semiconductor layer 408 reacts with an oxygen atom contained in an oxide semiconductor to be water, and thus sometimes forms oxygen vacancy (Vo). Furthermore, VoH is formed and the carrier concentration is increased in some cases. Forming the insulating layer 407a and the insulating layer 407c can reduce the number of oxygen vacancies (Vo) and VoH in the semiconductor layer 408, whereby the transistor can have favorable electric characteristics and high reliability.

The insulating layer 407a and the insulating layer 407c preferably have thicknesses with which the insulating layers function as blocking films against oxygen and hydrogen. When the insulating layer 407a and the insulating layer 407c are thin, the function of the blocking film might deteriorate. Meanwhile, when the insulating layer 407a and the insulating layer 407c are thick, a region where the semiconductor layer 408 is in contact with the insulating layer 407b is narrowed and the amount of oxygen supplied from the insulating layer 407b to the semiconductor layer 408 might be reduced. The insulating layer 407a and the insulating layer 407c can each be thinner than the insulating layer 407b.

In the transistor 100T, oxygen is supplied from the insulating layer 407 to the semiconductor layer 408, whereby the number of oxygen vacancies (Vo) and VoH in the channel formation region is reduced. Consequently, a transistor with favorable electrical characteristics and high reliability can be obtained.

A structure in which one or both of the insulating layer 407a and the insulating layer 407c are omitted may be employed.

### Conductive Layer 412a, Conductive Layer 412b, and Conductive Layer 404e

The conductive layer 412a, the conductive layer 412b, and the conductive layer 404e functioning as a source electrode, a drain electrode, and a gate electrode can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. For each of the conductive layer 412a, the conductive layer 412b, and the conductive layer 404e, a conductive material with low resistance that contains one or more of copper, silver, gold, and aluminum can be suitably used. Copper or aluminum is particularly preferable because of its high mass-productivity.

As the conductive layer 412a, the conductive layer 412b, and the conductive layer 404e, metal oxide films (also referred to as oxide conductors) can be used. Examples of the oxide conductor (OC) include In-Sn oxide (ITO), In-W oxide, In-W-Zn oxide, In-Ti oxide, In-Ti-Sn oxide, In-Zn oxide, In-Sn-Si oxide (ITSO), and In-Ga-Zn oxide.

Here, an oxide conductor (OC) will be described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus the metal oxide becomes a conductor. The metal oxide that has become a conductor can be referred to as an oxide conductor.

Each of the conductive layer 412a, the conductive layer 412b, and the conductive layer 404e may also have a stacked-layer structure of a conductive film containing the oxide conductor (the metal oxide) and a conductive film containing a metal or an alloy. The use of the conductive film including a metal or an alloy can reduce the wiring resistance.

A Cu-X alloy film (X is Mn, Ni, Cr, Fe, Co, Mo, Ta, or Ti) may also be used for each of the conductive layer 412a, the conductive layer 412b, and the conductive layer 404e. By employing a Cu-X alloy film, a wet etching process can be used in the processing, enabling the manufacturing cost savings.

Note that the same material can be used for each of the conductive layer 412a, the conductive layer 412b, and the conductive layer 404e. Alternatively, different materials can be used for the conductive layer 412a, the conductive layer 412b, and the conductive layer 404e.

Here, the conductive layer 412a and the conductive layer 412b will be described in detail with use of a structure in which a metal oxide is used for the semiconductor layer 408 as an example.

When an oxide semiconductor is used for the semiconductor layer 408, the conductive layer 412a and the conductive layer 412b are oxidized by oxygen contained in the semiconductor layer 408 and have high resistance in some cases. The conductive layer 412a and the conductive layer 412b are oxidized by oxygen contained in the insulating layer 407b and have high resistance in some cases. Moreover, when the conductive layer 412a and the conductive layer 412b are oxidized by oxygen contained in the semiconductor layer 408, the number of oxygen vacancies (Vo) in the semiconductor layer 408 is increased in some cases. When the conductive layer 412a and the conductive layer 412b are oxidized by oxygen contained in the insulating layer 407b, the amount of oxygen supplied from the insulating layer 407b to the semiconductor layer 408 might be reduced.

A material that is less likely to be oxidized is preferably used for each of the conductive layer 412a and the conductive layer 412b. An oxide conductor is preferably used for each of the conductive layer 412a and the conductive layer 412b. For example, In-Sn oxide (ITO) or In-Sn-Si oxide (ITSO) can be suitably used. An nitride conductor may also be used for the conductive layer 412a. Examples of the nitride conductor include tantalum nitride and titanium nitride. The conductive layer 412a can have a stacked-layer structure of the above-described materials.

The conductive layer 412a and the conductive layer 412b each containing a material that is less likely to be oxidized can be inhibited from being oxidized by oxygen contained in the semiconductor layer 408 or oxygen contained in the insulating layer 407b and having high resistance. Furthermore, it is possible to increase the amount of oxygen supplied from the insulating layer 407b to the semiconductor layer 408 while an increase in the number of oxygen vacancies (Vo) in the semiconductor layer 408 is inhibited. Accordingly, the number of oxygen vacancies (Vo) and VoH in the semiconductor layer 408 can be reduced, whereby the transistor can have favorable electric characteristics and high reliability.

Similarly, the conductive layer 412b containing a material that is less likely to be oxidized can be inhibited from having high resistance. Note that the same material can be used for each of the conductive layer 412a and the conductive layer 412b. Alternatively, different materials can also be used for the conductive layer 412a and the conductive layer 412b.

The conductive layer 412b has a region in contact with the transistor 100T. When a material that is less likely to be oxidized is used for the conductive layer 412b, the number of oxygen vacancies (Vo) and VoH in the semiconductor layer 408 can be reduced.

As described above, a material that is less likely to be oxidized is preferably used for each of the conductive layer 412a and the conductive layer 412b in contact with the semiconductor layer 408. However, the use of a material that is less likely to be oxidized might increase resistance. The conductive layer 412a and the conductive layer 412b function as wirings and thus preferably have low resistance. Thus, the conductive layer 412a and the conductive layer 412b can each be a stack of a material that is less likely to be oxidized and a material with low resistance, and the material that is less likely to be oxidized can be in contact with the semiconductor layer 408. With such a structure, the resistance of the conductive layer 412a and the conductive layer 412b can be reduced. Furthermore, the number of oxygen vacancies (Vo) and VoH in the semiconductor layer 408 can be reduced, whereby the transistor can have favorable electric characteristics and high reliability.

As the material that is less likely to be oxidized, one or more of an oxide conductor and a nitride conductor can be suitably used, for example. As the material with low resistance, one or more of copper, aluminum, titanium, tungsten, and molybdenum or an alloy containing one or more of these metals as its components can be suitably used, for example.

### Insulating Layer 406

The insulating layer 406 functioning as the gate insulating layer preferably has low defect density. With the insulating layer 406 having low defect density, the transistor can have favorable electrical characteristics. In addition, the insulating layer 406 preferably has high withstand voltage. With the insulating layer 406 having high withstand voltage, the transistor can have high reliability.

For the insulating layer 406, one or more of an insulating oxide, an insulating oxynitride, an insulating nitride oxide, and an insulating nitride can be used, for example. For the insulating layer 406, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga-Zn oxide can be used. The insulating layer 406 is not limited to a single-layer structure, and can have a stacked-layer structure. The insulating layer 406 may have a stacked-layer structure of an oxide and a nitride, for example.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 406 itself is preferably small. With the insulating layer 406 from which a small amount of impurities is released, diffusion of impurities into the semiconductor layer 408 is inhibited, and the transistor can have favorable electrical characteristics and high reliability.

Here, the insulating layer 406 will be described in detail, using a structure in which a metal oxide is used for the semiconductor layer 408 as an example.

An oxide is preferably used for, at least, the side of the insulating layer 406 being in contact with the semiconductor layer 408 in order to improve the interfacial properties with the semiconductor layer 408. For example, one or more of silicon oxide and silicon oxynitride can be suitably used for the insulating layer 406. A film from which oxygen is released by heating is further preferably used for the insulating layer 406.

The insulating layer 406 can also have a stacked-layer structure. The insulating layer 406 can have a stacked-layer structure of an oxide film on the side in contact with the semiconductor layer 408 and a nitride film on the side in contact with the conductive layer 404e. For example, one or more of silicon oxide and silicon oxynitride can be suitably used for the oxide film. Silicon nitride can be suitably used for the nitride film.

### Substrate 402

Although there is no particular limitation on a material of the substrate 402, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may also be used as the substrate 402. Alternatively, any of these substrates over which a semiconductor element is provided may also be used as the substrate 402. Note that the shape of the semiconductor substrate and an insulating substrate may also be a circular shape or a shape with corners.

A flexible substrate may be used as the substrate 402, and the transistor 100T and the like may also be formed directly on the flexible substrate. Alternatively, a separation layer may also be provided between the substrate 402 and the transistor 100T and the like. The separation layer can be used when part or the whole of a semiconductor device completed thereover is separated from the substrate 402 and transferred onto another substrate. In that case, the transistor 100T and the like can be transferred to a substrate having low heat resistance or a flexible substrate as well.

The above is the description of the components of the transistor 100T.

At least part of this embodiment can be implemented in combination with any of the other embodiments described in this specification as appropriate.

### Embodiment 4

In this embodiment, a display device of one embodiment of the present invention is described.

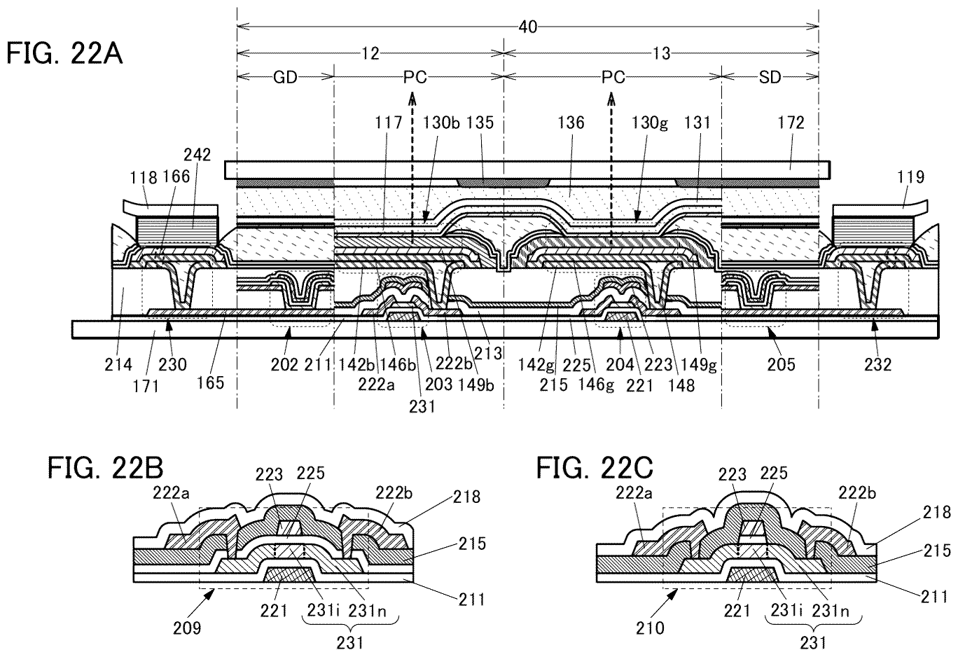

FIG. 22 is a cross-sectional view of a display device of one embodiment of the present invention.

FIG. 22 illustrates an example of cross sections of part of the pixel 12 and part of the pixel 13 in the display portion 40 of the display device illustrated in FIG. 1A. The pixel 12 is a region including the pixel circuit PC and components of the gate driver circuit GD, and the region 30 is a region including the pixel circuit PC and components of the source driver circuit SD (see FIG. 8 to FIG. 12).

The display device illustrated in FIG. 22A includes a transistor 202, a transistor 203, a transistor 204, a transistor 205, a light-emitting device 130b included in the pixel 12, a light-emitting device 130g included in the pixel 13, and the like between a substrate 171 and a substrate 172. Note that the light-emitting device 130b is illustrated as an example of a light-emitting device for performing blue light emission, and the light-emitting device 130g is illustrated as an example of a light-emitting device for performing green light emission.

The light-emitting device 130b includes a conductive layer 142b, a conductive layer 146b over the conductive layer 142b, and a conductive layer 149b over the conductive layer 146b. All of the conductive layers 142b, 146b, and 149b can be referred to as pixel electrodes, or one or two of them can be referred to as pixel electrodes.

The light-emitting device 130g includes a conductive layer 142g, a conductive layer 146g over the conductive layer 142g, and a conductive layer 149g over the conductive layer 146g.

The conductive layer 142b is connected to a conductive layer 222b included in the transistor 203 through an opening provided in an insulating layer 214. For example, a conductive layer functioning as a reflective electrode can be used as the conductive layer 142b and the conductive layer 146b, and a conductive layer functioning as a transparent electrode can be used as the conductive layer 149b.

The conductive layers 142b and 142g each have a depressed portion covering the opening provided in the insulating layer 214. A layer 148 is embedded in each of the depressed portions.

The layer 148 has a planarization function for the depressed portions of the conductive layers 142b and 142g. The conductive layers 146b and 146g electrically connected to the conductive layers 142b and 142g, respectively, are provided over the conductive layers 142b and 142g and the layer 148. Thus, regions overlapping with the depressed portions of the conductive layers 142b and 142g can also be used as light-emitting regions, increasing the aperture ratio of the pixel.

Not only an insulating layer but also a conductor layer can be used as the layer 148. Any of a variety of inorganic insulating materials, organic insulating materials, and conductive materials can be used for the layer 148 as appropriate. Specifically, the layer 148 is preferably formed using an insulating material and is particularly preferably formed using an organic insulating material.

The protective layer 131 is provided over the light-emitting devices 130b and 130g. An adhesive layer 136 is provided between the protective layer 131 and the substrate 172.

The display device has a top-emission structure. Light from the light-emitting device is emitted toward the substrate 172 side. For the substrate 172, a material having a high visible-light transmitting property is preferably used. The pixel electrode includes a material that reflects visible light, and a counter electrode (the common electrode 117) includes a material that transmits visible light.

The transistors 202 to 205 are formed over the substrate 171. The transistor 203 and the transistor 204 can be manufactured using the same material in the same step. The transistor 202 and the transistor 205 can be manufactured using the same material in the same step.

Transistors suitable for high-speed operation are preferably used for the gate driver circuit GD and the source driver circuit SD, and FIG. 22A illustrates an example in which vertical transistors are used as the transistor 202 and the transistor 205. Embodiment 3 can be referred to for the details of the vertical transistor.

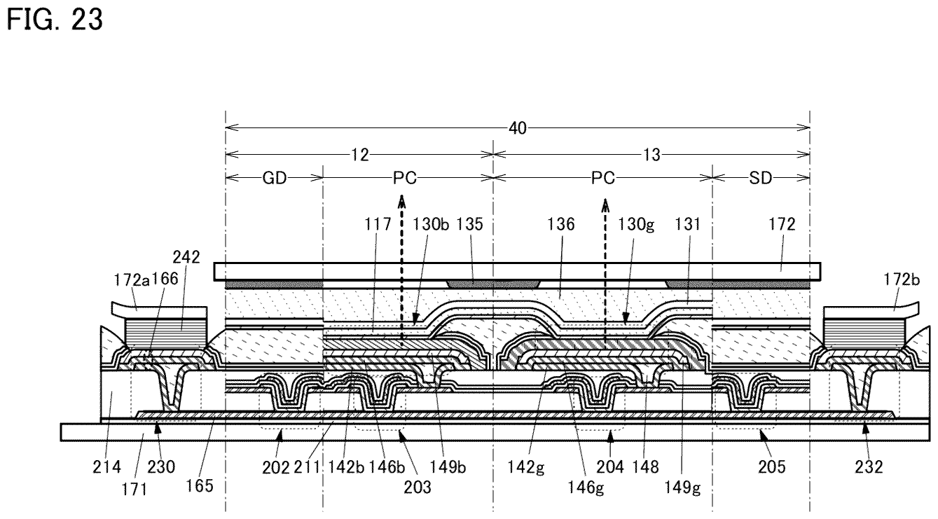

Note that as illustrated in FIG. 23, a vertical transistor can also be used as each of the transistor 203 and the transistor 204 included in the pixel circuit PC. With the use of the vertical transistor, the area occupied by the transistor is reduced, so that components of the driver circuits can be easily incorporated into the pixel. Furthermore, a correction circuit or the like can be easily incorporated in the pixel circuit.

An insulating layer 211, an insulating layer 213, an insulating layer 215, and the insulating layer 214 are provided in this order over the substrate 171. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material in which impurities such as water and hydrogen do not easily diffuse is preferably used for at least one of the insulating layers covering the transistors. In that case, the insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may also have a stacked-layer structure of an organic insulating layer and an inorganic insulating layer. The outermost layer of the insulating layer 214 preferably has a function of an etching protective layer. In that case, a depressed portion can be inhibited from being formed in the insulating layer 214 at the time of processing the conductive layer 142b, the conductive layer 146b, the conductive layer 149b, or the like. Alternatively, a depressed portion may also be formed in the insulating layer 214 at the time of processing the conductive layer 142b, the conductive layer 146b, the conductive layer 149b, or the like.

Each of the transistor 202 and the transistor 203 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a vertical transistor, a planar transistor, a fin-type transistor, a staggered transistor, an inverted staggered transistor, or the like can be used. Not only a top-gate transistor structure, but also a bottom-gate transistor structure can be employed. The gate can be provided on only one of the upper and lower sides of the semiconductor layer where the channel is formed, not necessarily on both sides.

The structure where the semiconductor layer where a channel is formed is held between two gates is used for each of the transistor 202 and the transistor 203. It is possible to drive the transistor by connecting the two gates and supplying the same signal to these gates. It is also possible to drive the transistor by applying a potential for controlling the threshold voltage to one of the two gates and a potential for driving to the other.

The semiconductor layer of the transistor preferably includes a metal oxide (also referred to as an oxide semiconductor). That is, an OS transistor including a metal oxide in its channel formation region is preferably used for the display device of this embodiment. For the metal oxide that can be used for the OS transistor, the description in Embodiment 3 can be referred to.

All the transistors included in the display device can be OS transistors. Alternatively, all the transistors included in the display device can be Si transistors. Alternatively, some of the transistors included in the display device may be OS transistors and the rest may be Si transistors.

Alternatively, an OS transistor may also be provided over a Si transistor. Alternatively, OS transistors may be stacked.

As examples of silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver) can be formed on the same substrate as a display portion. Thus, external circuits mounted on the display device can be simplified, and parts costs and mounting costs can be reduced.

When both an LTPS transistor and an OS transistor are used in the display portion 40, for example, a display device with low power consumption and high driving capability can be obtained. A structure where an LTPS transistor and an OS transistor are used in combination is referred to as LTPO in some cases. In a favorable example, it is preferable that an OS transistor be used as a transistor functioning as a switch for controlling electrical continuity and discontinuity between wirings and an LTPS transistor be used as a transistor for controlling current.

For example, one transistor included in the display portion 40 can function as a transistor for controlling current flowing through the light-emitting device and be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

By contrast, another transistor included in the display portion 40 functions as a switch for controlling selection and non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver circuit in displaying a still image.

As described above, the display device of one embodiment of the present invention can have all of a high aperture ratio, high definition, high display quality, and low power consumption.

Note that the display device of one embodiment of the present invention has a structure that includes the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display device. When the leakage current that would flow through the transistor and the lateral leakage current between the light-emitting devices are extremely low, light leakage that might occur in black display (what is called black-level degradation) or the like can be minimized.

FIG. 22B and FIG. 22C illustrate other structure examples of the transistor that can be used as the transistor 203 and the transistor 204.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistors may also be provided.

FIG. 22B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain. Meanwhile, in the transistor 210 illustrated in FIG. 22C, the insulating layer 225 overlaps with the channel formation region 231i of the semiconductor layer 231 and does not overlap with the low-resistance regions 231n. The structure illustrated in FIG. 22C can be formed by processing the insulating layer 225 using the conductive layer 223 as a mask, for example. In FIG. 22C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 230 is provided in a region of the substrate 171 where the substrate 172 does not overlap. In the connection portion 230, the wiring 165 is electrically connected to the FPC 118 through a conductive layer 166 and a connection layer 242. An example is described in which the conductive layer 166 has a stacked-layer structure of a conductive film obtained by processing the same conductive film as the conductive layers 142b and 142g, a conductive film obtained by processing the same conductive film as the conductive layers 146b and 146g, and a conductive film obtained by processing the same conductive film as the conductive layers 149b and 149g. The conductive layer 166 is exposed on the top surface of the connection portion 230. Thus, the connection portion 230 and the FPC 118 can be electrically connected to each other through the connection layer 242.

As the connection layer 242, an anisotropic conductive film (ACF), an anisotropic conductive paste (ACP), or the like can be used.

Note that a connection portion 232 to which an FPC 119 is electrically connected can have a structure similar to the above.

A light-blocking layer 135 can be provided between the adhesive layer 136 and the substrate 172. The light-blocking layer 135 can be provided to include a region overlapping with a region between the adjacent light-emitting devices and a region overlapping with a component of the driver circuit. Note that in order to improve color purity, a coloring layer can be provided to overlap with the light-emitting device.

As each of the substrate 171 and the substrate 172, a substrate made of the materials that can be used for the substrate 402 described in Embodiment 3 can be used. Alternatively, a silicon substrate where an arithmetic circuit, a memory circuit, and the like are formed can be used as the substrate 171. A variety of optical members such as a circular polarizing plate can be provided on the outer surface of the substrate 172.

At least part of this embodiment can be implemented in combination with any of the other embodiments described in this specification as appropriate.

### Embodiment 5

In this embodiment, electronic devices in which the display device of one embodiment of the present invention can be used will be described. The electronic device of one embodiment of the present invention can be used as a portable information terminal such as a smartphone or a tablet computer, for example.

The resolution of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a resolution of 4K, 8K, or higher is preferable. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment can include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, a current, a voltage, power, radiation, flow rate, humidity, a gradient, oscillation, odor, or infrared rays).

The electronic device of this embodiment can have a variety of functions. For example, the electronic device of this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

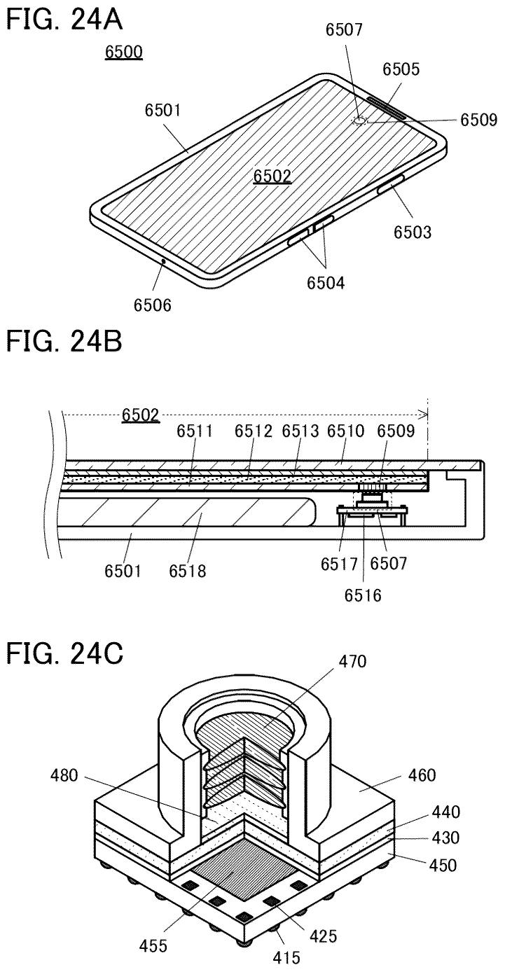

Next, an electronic device 6500 illustrated in FIG. 24A is a portable information terminal that can be used as a smartphone.

The electronic device 6500 includes a housing 6501, a display portion 6502, a power button 6503, buttons 6504, a speaker 6505, a microphone 6506, and a camera 6507. The display portion 6502 has a touch panel function.

The camera 6507 can be used as a front camera and is provided at a position overlapping with a punch hole 6509 provided in the display portion 6502. The display device of one embodiment of the present invention can be used for the display portion 6502. The display device of one embodiment of the present invention includes a driver circuit of a pixel circuit in the display portion, and thus can increase the degree of freedom in the shape of the display portion. Thus, even when the display portion 6502 has a region where a wiring cannot be provided, such as the punch hole 6509, an image can be displayed around the region.

FIG. 24B is a schematic cross-sectional view including an end portion of the housing 6501 on a camera 6507 side.

A protection member 6510 having a light-transmitting property is provided on a display surface side of the housing 6501, and a display panel 6511, an optical member 6512, a touch sensor panel 6513, a battery 6518, the camera 6507, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

A lens of the camera 6507 is placed to overlap with the punch hole 6509 of the display panel 6511. The camera 6507 can be mounted on the printed circuit board 6517 fixed to the housing 6501. An IC 6516 or the like including an arithmetic device or the like can be mounted on the printed circuit board 6517.

FIG. 24C is an external perspective view illustrating an example of a camera module with a combination of an image sensor chip and a lens. The camera module can be used for the camera 6507.

The package incorporating an image sensor chip is a CSP (Chip Size Package), which includes a bare chip 450 of an image sensor, cover glass 440, an adhesive 430 that bonds them, and the like.

Electrode pads 425 provided on the outside of a pixel array 455 are electrically connected to back electrodes 415 via through electrodes. The electrode pads 425 are electrically connected to a circuit included in the image sensor, with wirings or wires. Note that the bare chip 450 may be a stacked chip in which circuits having a variety of functions are stacked.

A BGA (Ball Grid Array) with a structure in which bumps are formed with solder balls is illustrated as an example of the back electrodes 415. Note that, without being limited to the BGA, an LGA (Land Grid Array), a PGA (Pin Grid Array), or the like can be used. Alternatively, a package in which the bare chip 450 is mounted on a QFN (Quad Flat No-lead package) or a QFP (Quad Flat Package) can be used.

A lens cover 460, a plurality of lenses 470, and the like are provided over the package. Furthermore, an optical filter 480 that absorbs light with a particular wavelength is provided as needed between the lens 470 and the cover glass 440. For example, in the case where the image sensor mainly performs visible light imaging, an infrared cut filter or the like can be used as the optical filter 480.

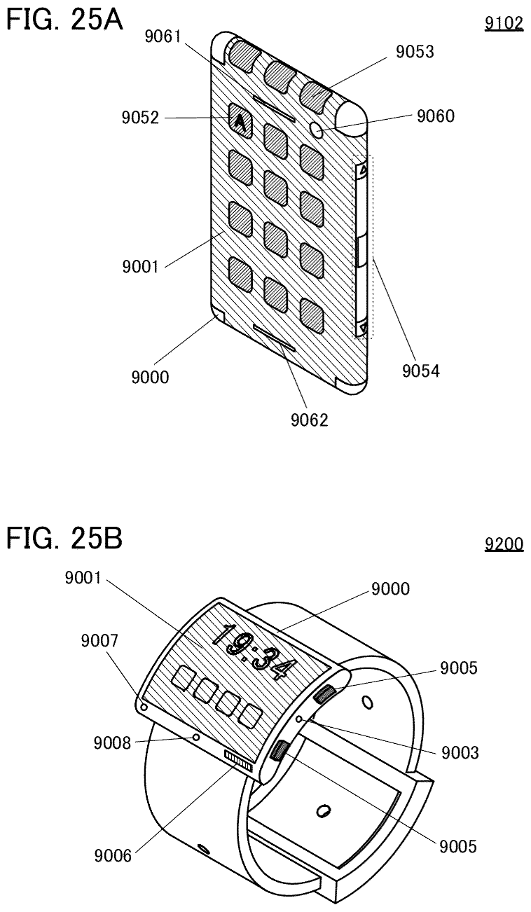

FIG. 25A is a perspective view illustrating an electronic device 9102 having a mode different from that in FIG. 24A. The electronic device 9102 has a function of displaying information on three or more surfaces of a display portion 9001 provided in a housing 9000. Here, an example in which an image 9052, an image 9053, and an image 9054 are displayed on different surfaces is illustrated. For example, the user of the electronic device 9102 can check the image 9053 displayed such that it can be seen from above the electronic device 9102, with the electronic device 9102 put in a breast pocket of his/her clothes. The user can see the display without taking out the electronic device 9102 from the pocket and decide whether to answer the call, for example.

The display device of one embodiment of the present invention can be used in the display portion 9001. The structure including a driver circuit for the pixel circuit in the display portion can be formed over a flexible substrate, and can also be applied to a device in which an end portion of the display portion is rolled as illustrated in FIG. 25.

In the case of using such a device, a driver circuit is suitably provided at an end portion of the display portion, for example. The rolled end portion of the display portion is not used for viewing of high-definition display, and an image such as an icon is displayed on the rolled end portion in almost all cases. Thus, the pixel density of a region where the driver circuit is provided can be reduced (the resolution can be reduced). A reduction in pixel density can increase the area occupied by a pixel, so that a component of the driver circuit can be easily incorporated in the pixel.

As in FIG. 24A, a punch hole 9060 can be provided. A camera can be provided to overlap with the punch hole 9060. Moreover, the camera can be used as a light adjustment sensor and can be used as a sensor for adjusting the luminance of display in accordance with the ambient illuminance.

An opening portion 9061 overlapping with a call speaker and an opening portion 9062 overlapping with a call microphone can also be provided in the display portion. The opening portions 9061 and 9062 are regions where a wiring cannot be provided, like the punch hole 9060; however, the display device of one embodiment of the present invention includes a driver circuit of a pixel circuit in its display portion, enabling an image to be displayed around the opening portions 9061 and 9062.

FIG. 25B is a perspective view of a watch-type electronic device 9200. The electronic device 9200 can include a housing 9000, a display portion 9001, a speaker 9003, operation keys 9005, a connection terminal 9006, a sensor 9007, and the like. The display surface of the display portion 9001 is curved, and display can be performed along the curved display surface.

Furthermore, mutual communication between the electronic device 9200 and, for example, a headset capable of wireless communication enables hands-free calling. With the connection terminal 9006, the electronic device 9200 can perform mutual data transmission with another information terminal and charging. Note that the charging operation may be performed by wireless power feeding.

The display device of one embodiment of the present invention can be used in the display portion 9001. As described in Embodiment 1, the display device of one embodiment of the present invention is effective also in the case where the display surface has a curved surface; by providing a driver circuit in the display portion, the display device can have a narrower bezel, and the watch-type electronic device with high design flexibility can be manufactured.

At least part of this embodiment can be implemented in combination with any of the other embodiments described in this specification as appropriate.

### REFERENCE NUMERALS

Ca capacitor
Cb: capacitor, Cd: capacitor, Ce: capacitor, Cf: capacitor, GD: gate driver circuit, GL: gate line, L1: latch circuit, L2: latch circuit, M10: transistor, M11: transistor, M12: transistor, M13: transistor, M14: transistor, M15: transistor, SD: source driver circuit, SF: source follower circuit, SL: source line, SR: shift register circuit, 10: region, 11: pixel, 12: pixel, 13: pixel, 20: region, 21: component, 30: region, 31: component, 40: display portion, 45: substrate, 50: punch hole, 100a: display panel, 100b: display panel, 100T: transistor, 100: display panel, 101: substrate, 110a: light-emitting element, 110B: light-emitting element, 110b: light-emitting element, 110c: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 116B: coloring layer, 116G: coloring layer, 116R: coloring layer, 117: common electrode, 118: FPC, 119: FPC, 121: protective layer, 122: insulating layer, 123: insulating layer, 124a: pixel, 124b: pixel, 125: insulating layer, 126: resin layer, 128: layer, 130b: light-emitting device, 130g: light-emitting device, 131: protective layer, 135: light-blocking layer, 136: adhesive layer, 140: connection portion, 142b: conductive layer, 142g: conductive layer, 146b: conductive layer, 146g: conductive layer, 148: layer, 149b: conductive layer, 149g: conductive layer, 150: pixel, 165: wiring, 166: conductive layer, 171: substrate, 172: substrate, 202: transistor, 203: transistor, 204: transistor, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 230: connection portion, 231i: channel formation region, 231n: low-resistance region, 231: semiconductor layer, 232: connection portion, 242: connection layer, 402: substrate, 404e: conductive layer, 404: conductive layer, 406: insulating layer, 407a: insulating layer, 407b: insulating layer, 407c: insulating layer, 407: insulating layer, 408: semiconductor layer, 412a: conductive layer, 412b: conductive layer, 415: back electrode, 425: electrode pad, 430: adhesive, 440: cover glass, 441: opening, 450: bare chip, 455: pixel array, 460: lens cover, 470: lens, 480: optical filter, 6500: electronic device, 6501: housing, 6502: display portion, 6503: power button, 6504: button, 6505: speaker, 6506: microphone, 6507: camera, 6509: punch hole, 6510: protection member, 6511: display panel, 6512: optical member, 6513: touch sensor panel, 6516: IC, 6517: printed circuit board, 6518: battery, 9000: housing, 9001: display portion, 9003: speaker, 9005: operation key, 9006: connection terminal, 9007: sensor, 9052: image, 9053: image, 9054: image, 9060: punch hole, 9061: opening portion, 9062: opening portion, 9102: electronic device, 9200: electronic device

1. A display device comprising:
a first region, a second region, and a third region in a display portion,
wherein the first region comprises a first pixel,
wherein the second region comprises a second pixel,
wherein the third region comprises a third pixel,
wherein the first pixel, the second pixel, and the third pixel each comprise a pixel circuit,
wherein the second pixel further comprises at least a component of a first circuit,
wherein the third pixel further comprises at least a component of a second circuit, and
wherein the second region and the third region are arranged to be orthogonal to each other.

2. (canceled)

3. The display device according to claim 1,
wherein the first circuit is configured to be a gate driver circuit, and the second circuit is configured to be a source driver circuit.

4. The display device according to claim 1,
wherein the first circuit comprises a first shift register circuit, and
wherein the second circuit comprises a second shift register circuit, a first latch circuit, a second latch circuit, and a source follower circuit.

5. A display device comprising:
a first region, a second region, and a third region in a display portion,
wherein the first region comprises a first pixel,
wherein the second region comprises a second pixel,
wherein the third region comprises a third pixel,
wherein the first pixel, the second pixel, and the third pixel each comprise a pixel circuit,
wherein the second pixel further comprises at least a component of a gate driver circuit,
wherein the third pixel further comprises at least a component of a source driver circuit, and
wherein the first region is a region except the second region and the third region in the display portion, and the second region and the third region each have a belt-like shape and are arranged to be orthogonal to each other.

6. The display device according to claim 5,
wherein the gate driver circuit comprises a first shift register circuit, and
wherein the source driver circuit comprises a second shift register circuit, a first latch circuit, a second latch circuit, and a source follower circuit.

7. The display device according to claim 1,
wherein the pixel circuit comprises a light-emitting device.

8. The display device according to claim 1,
wherein the pixel circuit comprises a transistor comprising a metal oxide in a semiconductor layer.

9. The display device according to claim 8,
wherein a channel formation region of the transistor is provided along a side surface of an insulating layer.

10. The display device according to claim 1,
wherein an outer periphery of the display portion has a curved portion, and a plurality of pixels are provided along the curved portion.

11. The display device according to claim 1,
wherein the display portion has a curved surface.

12. The display device according to claim 1,
wherein an opening portion is provided in the first region.

13. An electronic device comprising:
the display device according to claim 12, and
a camera,
wherein the opening portion and a lens of the camera overlap with each other.

14. The display device according to claim 5,
wherein the pixel circuit comprises a light-emitting device.

15. The display device according to claim 5,
wherein the pixel circuit comprises a transistor comprising a metal oxide in a semiconductor layer.

16. The display device according to claim 15,
wherein a channel formation region of the transistor is provided along a side surface of an insulating layer.

17. The display device according to claim 5,
wherein an outer periphery of the display portion has a curved portion, and a plurality of pixels are provided along the curved portion.

18. The display device according to claim 5,
wherein the display portion has a curved surface.

19. The display device according to claim 5,
wherein an opening portion is provided in the first region.

20. An electronic device comprising:
the display device according to claim 19, and
a camera,
wherein the opening portion and a lens of the camera overlap with each other.
